(19) United States
(12) Patent Application Publication
(10) Pub. No.: US 2025/0204209 A1
(43) Pub. Date: Jun. 19, 2025

(54) DISPLAY DEVICE WITH CRACK PROTECTION AREA

(71) Applicant: SAMSUNG DISPLAY CO., LTD., YONGIN-SI (KR)

(72) Inventors: Ki Ho BANG, YONGIN-SI (KR); Dong Won KIM, YONGIN-SI (KR); Min Jung NA, YONGIN-SI (KR); Ji Su SHIN, YONGIN-SI (KR); Deok Won YANG, YONGIN-SI (KR); In Hyuck YEO, YONGIN-SI (KR); Hang Jae LEE, YONGIN-SI (KR); Won Suk CHOI, YONGIN-SI (KR)

(21) Appl. No.: 18/767,097

(22) Filed: Jul. 9, 2024

(30) Foreign Application Priority Data
Dec. 15, 2023 (KR) 10-2023-0182525

(51) Int. Cl. H10K 59/80; H10K 59/121; H10K 59/131; H10K 59/40; H10K 77/10

(52) U.S. Cl. CPC H10K 59/871; H10K 59/1213; H10K 59/131; H10K 59/40; H10K 77/111

(57) ABSTRACT

A display device include a display panel. The display panel includes a substrate; a circuit layer disposed on the substrate; and an emission layer disposed on the circuit layer. A main area of the substrate includes a display area where emission areas are arranged and a non-display area disposed around the display area. The display area includes a front display area and a peripheral display area disposed around the front display area and having a curved shape. The substrate includes a first support layer; a barrier layer disposed on a portion of the first support layer; and a second support layer covering the barrier layer. The substrate further includes a crack protection area in contact with at least a portion of an edge of the substrate. The second support layer is in contact with the first support layer in the crack protection area.

### CROSS-REFERENCE TO RELATED APPLICATION

This patent application claims priority under 35 U.S.C. 119 to Korean Patent Application No. 10-2023-0182525 filed on Dec. 15, 2023 in the Korean Intellectual Property Office, the disclosure of which is incorporated by reference in its entirety herein.

### 1. TECHNICAL FIELD

The present disclosure is directed to a display device with a crack protection area.

### 2. DISCUSSION OF RELATED ART

The demand for display devices has steadily increased with the development of multimedia technology. For example, display devices have been applied to various electronic devices such as smartphones, digital cameras, laptop computers, navigation devices, and smart televisions.

The display devices may be flat panel display devices such as liquid crystal display devices, field emission display devices, or light emitting display devices. For example, the light emitting display device may include an organic light emitting display device including organic light emitting elements, an inorganic light emitting display device including inorganic light emitting elements such as inorganic semiconductors, and a micro light emitting display device including micro light emitting elements.

The organic light emitting display device displays an image using self-light emitting elements, and accordingly, may have relatively excellent performance in terms of power consumption, response speed, luminous efficiency, luminance, and a wide viewing angle, compared to other display devices.

However, organic light emitting display devices are vulnerable to cracking. The thinness of organic emitting display device makes them more susceptible to damage from impact, bending, or pressure, which can result in cracks. Thus, there is a need for organic light emitting display devices that are more resilient to cracking.

### SUMMARY

When a display area of a display surface of a display device is very wide, an area of the display device where the light is emitted is also very wide, which may be more aesthetically pleasing and more compatible with various electronic devices. A width of a non-display area of the display surface may be reduced to increase the width of the display area. However, since some signal lines and circuit elements need to be disposed in the non-display area, there is a limit to how much the width of the non-display area can be reduced. Further, reducing the width of the non-display area may make the display device more susceptible to cracking.

At least one embodiment of the present disclosure provides a display device in which a width of a non-display area viewed in a front direction facing a display surface may be reduced by transforming an edge of a display area into a curved shape.

According to an aspect of the present disclosure, there is provided a display device including a display panel to emit light for displaying an image. The display panel includes a substrate; a circuit layer disposed on the substrate; and an emission layer disposed on the circuit layer. A main area of the substrate includes a display area where emission areas are arranged and a non-display area disposed around the display area. The display area includes a front display area and a peripheral display area disposed around the front display area and having a curved shape. The substrate includes a first support layer; a barrier layer disposed on a portion of the first support layer; and a second support layer covering the barrier layer. The substrate further includes a crack protection area in contact with at least a portion of an edge of the substrate. The second support layer is in contact with the first support layer in the crack protection layer.

The front display area may include a first side and a second side that extend in a first direction and oppose each other and a third side and a fourth side that extend in a second direction crossing the first direction and oppose each other. The peripheral display area may include a first side area, a second side area, a third side area, and a fourth side area in contact with the first side, the second side, the third side, and the fourth side of the front display area, respectively; a first corner area in contact with a vertex where the first side and the third side meet and disposed between the first side area and the third side area; a second corner area in contact with a vertex where the second side and the third side meet and disposed between the second side area and the third side area; a third corner area in contact with a vertex where the second side and the fourth side meet and disposed between the second side area and the fourth side area; and a fourth corner area in contact with a vertex where the first side and the fourth side meet and disposed between the first side area and the fourth side area.

The barrier layer may overlap the display area of the main area.

The emission layer may include light emitting elements respectively disposed in the emission areas. The circuit layer includes emission pixel drivers arranged in the first direction and the second direction in the display area and electrically connected to the light emitting elements, respectively; gate lines extending in the first direction and transmitting gate signals to the emission pixel drivers; and a gate driver disposed in a gate circuit area facing at least one side of the display area among the non-display area in the first direction and supplying gate signals to the gate lines. The barrier layer may extend to the non-display area to further overlap the gate circuit area.

The display panel may further include a sealing layer disposed on the element layer; and at least one dam portion arranged in a dam area of the non-display area surrounding the display area and spaced apart from the display area. The barrier layer may extend to the non-display area to further overlap the dam area. The crack protection area may be disposed between the dam area and the edge of the substrate.

The edge of the main area includes fifth and sixth sides extending in a first direction and facing each other; seventh and eighth sides extending in a second direction crossing the first direction and facing each other; a first corner where the fifth side and the seventh side meet; a second corner where the sixth side and the seventh side meet; a third corner where the sixth side and the eighth side meet; and a fourth corner where the fifth side and the eighth side meet. The crack protection area is in contact with at least one of the first corner, the second corner, the third corner, and the fourth corner among the edge of the main area.

The substrate further may include a sub-area protruding from at least a portion of the fifth side. The crack protection area may be in further contact with the seventh side, the sixth side, and the eighth side among the edges of the main area. The crack protection area may be in further contact with a portion of the fifth side of the edge of the main area other than a portion of the main area in contact with the sub-area.

The sub-area may include a bending area connected to the main area, and a pad area connected to the bending area. The crack protection area may include the bending area.

The crack protection area may be in further contact with a portion of the edge of the sub-area other than a portion of the sub-area connected to the main area.

Each of the first support layer and the second support layer may include an organic insulating material. The barrier layer may include an inorganic insulating material.

The circuit layer may further include a first semiconductor layer disposed on the substrate; a first gate insulating layer covering the first semiconductor layer; a first gate conductive layer disposed on the first gate insulating layer; a second gate insulating layer covering the first gate conductive layer; a second gate conductive layer disposed on the second gate insulating layer; an interlayer insulating layer disposed on the second gate insulating layer and the second gate conductive layer; a first source/drain conductive layer disposed on the interlayer insulating layer; a first planarization layer covering the first source/drain conductive layer; a second source/drain conductive layer disposed on the first planarization layer; and a second planarization layer covering the second source/drain conductive layer.

The circuit layer may further include an auxiliary interlayer insulating layer covering the second gate conductive layer; a second semiconductor layer disposed on the auxiliary interlayer insulating layer; a third gate insulating layer covering the second semiconductor layer; and a third gate conductive layer disposed on the third gate insulating layer and covered by the interlayer insulating layer.

The display device may further include a bracket supporting the display panel; and a cover window disposed on the display panel and coupled to the bracket. The peripheral display area may have a shape curved toward the bracket.

According to an aspect of the present disclosure, there is provided a display device including a display panel to emit light for displaying an image; a bracket supporting the display panel; and a cover window disposed on the display panel and coupled to the bracket. The display panel includes a substrate; a circuit layer disposed on the substrate; and an emission layer disposed on the circuit layer. A main area of the substrate includes a display area where emission areas are arranged and a non-display area disposed around the display area. The display area includes a front display area and a peripheral display area disposed around the front display area and having a shape curved toward the bracket. The substrate includes a first support layer; a barrier layer disposed on a portion of the first support layer and including a material different from the first support layer; and a second support layer covering the barrier layer and including a same material as the first support layer. The substrate further includes a crack protection area in contact with at least a portion of the edge of the substrate. The second support layer is in contact with the first support layer in the crack protection area.

The front display area may include a first side and a second side extending in a first direction and facing each other and a third side and a fourth side extending in a second direction crossing the first direction and facing each other. The peripheral display area may include a first side area, a second side area, a third side area, and a fourth side area in contact with the first side, the second side, the third side, and the fourth side of the front display area, respectively; a first corner area in contact with a vertex where the first side and the third side meet and disposed between the first side area and the third side area; a second corner area in contact with a vertex where the second side and the third side meet and disposed between the second side area and the third side area; a third corner area in contact with a vertex where the second side and the fourth side meet and disposed between the second side area and the fourth side area; and a fourth corner area in contact with a vertex where the first side and the fourth side meet and disposed between the first side area and the fourth side area.

The barrier layer may overlap the display area of the main area.

The emission layer may include light emitting elements respectively disposed in the emission areas. The circuit layer may include emission pixel drivers arranged in the first direction and the second direction in the display area and electrically connected to the light emitting elements, respectively; gate lines extending in the first direction and transmitting gate signals to the emission pixel drivers; and a gate driver disposed in a gate circuit area facing at least one side of the display area among the non-display area in the first direction and supplying gate signals to the gate lines. The barrier layer may extend to the non-display area to further overlap the gate circuit area.

The display panel may further include a sealing layer disposed on the element layer; and at least one dam portion arranged in a dam area of the non-display area surrounding the display area and spaced apart from the display area. The edge of the main area may include fifth and sixth sides extending in a first direction and facing each other; seventh and eighth sides extending in a second direction crossing the first direction and facing each other; a first corner where the fifth side and the seventh side meet; a second corner where the sixth side and the seventh side meet; a third corner where the sixth side and the eighth side meet; and a fourth corner where the fifth side and the eighth side meet. The crack protection area may be in contact with the first corner, the second corner, the third corner, and the fourth corner among the edge of the main area, disposed between the dam area and the edge of the substrate. The barrier layer may extend to the non-display area to further overlap the dam area.

The substrate may further include a sub-area protruding from a portion of the fifth side. The crack protection area may be in further contact with the seventh side, the sixth side, and the eighth side among the edges of the main area. The crack protection area may be in further contact with a portion of the fifth side of the edge of the main area other than a portion of the main area in contact with the sub-area.

The crack protection area may be in further contact with a portion of the edge of the sub-area other than a portion of the sub-area adjacent to the main area.

A display device according to an embodiment may include a display panel to emit light for displaying an image, and a main area of a substrate of the display panel may include a display area where emission areas are arranged and a non-display area disposed around the display area. The display area may include a front display area and a peripheral display area disposed around the front display area and having a curved shape.

According to an embodiment, the peripheral display area may include a first side area, a second side area, a third side area, and a fourth side area in contact with a first side, a second side, a third side, and a fourth side of the front display area, respectively, and a first corner area, a second corner area, a third corner area, and a fourth corner area in contact with vertices where any two of the first side, the second side, the third side, and the fourth side of the front display area meet.

As described above, the display area according to an embodiment includes the peripheral display area having the curved shape, and accordingly, the non-display area connected to the peripheral display area may have a curved shape along with the peripheral display area. That is, a width of the non-display area having the curved shape, viewed in a front direction facing a display surface may be smaller than a width of the non-display area in a non-curved state. Accordingly, a width of the display area of the display surface of the display device viewed in the front direction may increase, and thus, aesthetics and compatibility of the display device may be increased.

According to an embodiment, the substrate of the display panel may include a first support layer, a barrier layer disposed on a portion of the first support layer, and a second support layer covering the barrier layer.

According to an embodiment, the substrate may include a crack protection area in contact with at least a portion of the edges of the substrate.

According to an embodiment, in the crack protection area, the barrier layer may be removed so that the second support layer in in contact with the first support layer.

As described above, the barrier layer may be removed from at least a portion of the edges of the substrate, and accordingly, only a portion of the barrier layer may be exposed in a process of separating the substrate from a parent substrate and a process of modifying a peripheral display area to a curved shape. Accordingly, cracks in the barrier layer can be reduced and prevented. As a result, substrate separation defects in which the first support layer and the second support layer are separated due to cracks in the barrier layer can be prevented.

Accordingly, the lifespan and quality reliability of the display device can be increased.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating a display device according to an embodiment;

FIG. 2 is a cross-sectional view taken along line A-A′ of FIG. 1;

FIG. 3 is a plan view illustrating a display panel of FIG. 2;

FIG. 4 is a layout diagram illustrating portion C of FIG. 3;

FIG. 5 is a cross-sectional view of the display panel taken along line B-B′ of FIG. 1;

FIG. 6 is a layout diagram illustrating a touch sensor layer of FIG. 5 according to an embodiment;

FIG. 7 is a detailed plan view illustrating portion D of FIG. 6;

FIG. 8 is an equivalent circuit diagram illustrating an emission pixel driver of FIG. 4 according to an embodiment;

FIG. 9 is cross-sectional view taken along line E-E′ of FIG. 7 according to an embodiment of FIG. 8;

FIG. 10 is an equivalent circuit diagram illustrating an emission pixel driver of FIG. 4 according to an embodiment;

FIG. 11 is a cross-sectional view taken along line E-E′ of FIG. 7 according to an embodiment of FIG. 10;

FIG. 12 is a plan view illustrating a substrate according to an embodiment;

FIG. 13 is a cross-sectional view illustrating a display panel taken along line F-F′ of FIG. 12; and

FIGS. 14, 15, 16, 17, 18, and 19 are plan views of substrates according to embodiments.

### DETAILED DESCRIPTION

Features of the present disclosure and methods of accomplishing the same may be understood more readily by reference to the following detailed description of exemplary embodiments and the accompanying drawings. The present disclosure may, however, be embodied in many different forms and should not be construed as being limited to the embodiments set forth herein. Rather, these embodiments are provided so that this disclosure will be thorough and complete and will fully convey the concept of the present disclosure to those skilled in the art.

It will be understood that when an element or layer is referred to as being “on” another element or layer, the element or layer can be directly on another element or layer or intervening elements or layers. Like reference numerals refer to like elements throughout the specification. Shapes, sizes, ratios, angles, numbers, etc. disclosed in the drawings for describing embodiments are merely an example, and the present disclosure is not limited to the illustrated details.

Features of various embodiments of the present disclosure may be partially or entirely coupled to or combined with each other, and may be inter-operated and driven in technically various ways. The embodiments may be implemented independently from each other, or may be implemented together in a co-dependent relationship.

Hereinafter, specific embodiments will be described with reference to the accompanying drawings.

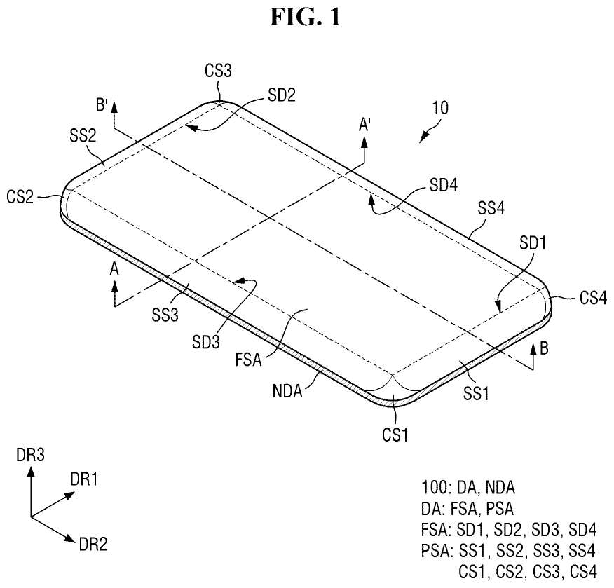

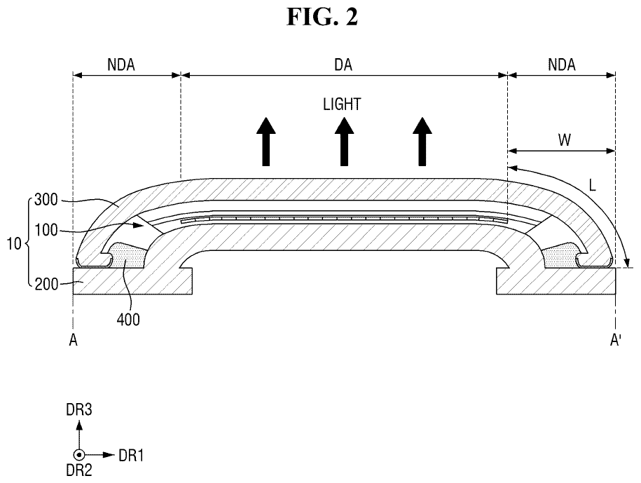

FIG. 1 is a perspective view illustrating a display device according to an embodiment. FIG. 2 is a cross-sectional view taken along line A-A′ of FIG. 1.

Referring to FIG. 1, a display device 10 according to an embodiment is a device that displays a moving image or a still image, and may be used as a display screen of various products such as televisions, laptop computers, monitors, billboards, and the Internet of Things (IOT) as well as portable electronic devices such as mobile phones, smartphones, tablet personal computers (PCs), smart watches, watch phones, mobile communication terminals, electronic notebooks, electronic books, portable multimedia players (PMPs), navigation devices, and ultra mobile PCs (UMPCs).

Alternatively, the display device 10 according to embodiments may be applied to a center information display (CID) disposed on an instrument board, a center fascia, or a dashboard of a vehicle, a room mirror display substituting for a side-view mirror of the vehicle, or a display disposed on a rear surface of a front seat as entertainment for a rear seat of the vehicle.

Referring to FIG. 2, the display device 10 according to an embodiment includes a display panel 100 emitting light for displaying an image.

In addition, the display device 10 according to an embodiment further includes a bracket 200 supporting the display panel 100 and a cover window 300 disposed on the display panel 100 and coupled to the bracket 200.

The display panel 100 may be a light emitting display panel including light emitting elements. For example, the display panel 100 may be an organic light emitting display panel using organic light emitting diodes including organic light emitting layers, a micro light emitting diode display panel using micro light emitting diodes (LEDs), a quantum dot light emitting display panel using quantum dot light emitting diodes including quantum dot light emitting layers, or an inorganic light emitting display panel using inorganic light emitting elements including inorganic semiconductors. Hereinafter, it will be mainly described that the display panel 100 is an organic light emitting display panel.

The bracket 200 may include a rigid insulating material to prevent deformation of the display panel 100, alleviate external physical and reduce electrical shocks to the display panel 100. However, this is only an example since the bracket 200 may be changed to include a different material.

The cover window 300 may include a light transmitting material. The cover window 300 may be made of an inorganic material such as glass or made of an organic material such as plastic or a polymer material. The cover window 300 may be fastened to the bracket 200 through an adhesive material 400 disposed at an edge thereof. The cover window 300 may also be attached onto the display panel 100 by a transparent adhesive member such as an optically clear adhesive (OCA) film or an optically clear resin (OCR). A display surface the display panel 100 may be protected from electrical and physical shocks due to the cover window 300.

As illustrated in FIG. 1, according to an embodiment, the display panel 100 includes a display area DA where light is emitted and a non-display area NDA disposed around the display area DA.

The display area DA may include a front display area FSA having a flat shape and a peripheral display area PSA disposed around the front display area FSA and having a curved shape.

The front display area FSA may include a first side SD1 and a second side SD2 that extend in a first direction DR1 and oppose each other and a third side SD3 and a fourth side SD4 that extend in a second direction DR2, connect the first side SD1 and the second side SD2 to each other, and oppose each other.

As an example, the first side SD1 and the second side SD2 may be shorter than the third side SD3 and the fourth side SD4. That is, the front display area FSA may have a quadrangular shape in a plan view.

As another example, corners where each of the first side SD1 and the second side SD2 and each of the third side SD3 and the fourth side SD4 meet may be formed as arcs or vertices having a right-angled shape.

However, a shape of the front display area FSA according to embodiments is not limited to the quadrangular shape illustrated in FIG. 1, and may also be a polygonal shape other than the quadrangular shape, a circular shape, or an elliptical shape.

The peripheral display area PSA may include a first side area SS1 in contact with the first side SD1 of the front display area FSA, a second side area SS2 in contact with the second side SD2 of the front display area FSA, a third side area SS3 in contact with the third side SD3 of the front display area FSA, and a fourth side area SS4 in contact with the fourth side SD4 of the front display area FSA.

In addition, the peripheral display area PSA may further include a first corner area CS1, a second corner area CS2, a third corner area CS3 and a fourth corner area CS4. The first corner area CS1 is in contact with a vertex where the first side SD1 and the third side SD3 are connected to each other and is disposed between the first side area SS1 and the third side area SS3. The second corner area CS2 is in contact with a vertex where the second side SD2 and the third side SD3 are connected to each other and is disposed between the second side area SS2 and the third side area SS3. The third corner area CS3 is in contact with a vertex where the second side SD2 and the fourth side SD4 are connected to each other and is disposed between the second side area SS2 and the fourth side area SS4. The fourth corner area CS4 is in contact with a vertex where the first side SD1 and the fourth side SD4 are connected to each other and is disposed between the first side area SS1 and the fourth side area SS4.

The first side area SS1 may have a shape in which it extends from the first side SD1 and is curved with a predetermined first curvature toward the bracket 200.

The second side area SS2 may have a shape in which it extends from the second side SD2 and is curved with a second curvature toward the bracket 200. The second curvature may be in a range that is the same as that of the first curvature.

The third side area SS3 may have a shape in which it extends from the third side SD3 and is curved with a predetermined third curvature toward the bracket 200. The third curvature may be in a range that is the same as or similar to that of the first curvature or the second curvature, but is not limited thereto. For example, the first through third curvatures may fall within similar numerical intervals.

The fourth side area SS4 may have a shape in which it extends from the fourth side SD4 and is curved with a fourth curvature toward the bracket 200. The fourth curvature may be in a range that is the same as that of the third curvature. For example, the third and fourth curvatures may fall within similar numerical intervals.

The first corner area CS1 may be disposed between the other side of the first side area SS1 and one side of the third side area SS3.

The first corner area CS1 may be a double-curvature area curved with the first curvature of the first side area SS1 and the third curvature of the third side area SS3.

The second corner area CS2 may be disposed between one side of the second side area SS2 and the other side of the third side area SS3.

The second corner area CS2 may be a double-curvature area curved with the second curvature of the second side area SS2 and the third curvature of the third side area SS3.

The third corner area CS3 may be disposed between the other side of the second side area SS2 and one side of the fourth side area SS4.

The third corner area CS3 may be a double-curvature area curved with the second curvature of the second side area SS2 and the fourth curvature of the fourth side area SS4.

The fourth corner area CS4 may be disposed between one side of the first side area SS1 and the other side of the fourth side area SS4.

The fourth corner area CS4 may be a double-curvature area curved with the first curvature of the first side area SS1 and the fourth curvature of the fourth side area SS4.

That is, since each of the first corner area CS1, the second corner area CS2, the third corner area CS3, and the fourth corner area CS4 is a double-curvature area affected by two different curvatures, a higher bending stress may be applied to these corner areas compared to the first side area SS1, the second side area SS2, the third side area SS3, and the fourth side area SS4.

Accordingly, cracks due to relatively high bending stress may occur more frequently in the first corner area CS1, the second corner area CS2, the third corner area CS3, and the fourth corner area CS4 and a portion of the non-display area NDA adjacent thereto.

As described above, according to an embodiment, the display area DA includes not only the front display area FSA having the flat shape, but also the peripheral display area PSA having the shape curved toward the bracket 200.

The non-display area NDA is disposed around the display area DA, and may thus be connected to an outer side of the peripheral display area PSA.

That is, the non-display area NDA connected to the peripheral display area PSA having the curved shape may have a curved shape along with the peripheral display area PSA having the curved shape.

As illustrated in FIG. 2, the display device 10 may include a display area DA where light of the display panel 100 is emitted and a non-display area NDA which is disposed around the display area DA and where light is not emitted.

The display area DA of the display panel 100 may have a shape in which the peripheral display area PSA (see FIG. 1) of an edge thereof is curved toward the bracket 200. Accordingly, the non-display area NDA of the display device 10 may be disposed on side surfaces of the display device 10 due to the peripheral display area PSA having the curved shape.

In addition, each of the bracket 200 and the cover window 300 may have a shape in which an edge thereof is curved like the display panel 100.

Accordingly, a width W of the non-display area NDA having the curved shape in the display device 10, viewed in a front direction (e.g., an opposite direction to a third direction DR3) facing light LIGHT of the front display area FSA (see FIG. 1) of the display device 10 may be smaller than a width L of the non-display area NDA in a non-curved state.

Therefore, as the width W of the non-display area NDA viewed in the front direction in a display surface of the display device 10 decreases, a ratio of the display area DA of the display surface may increase, and thus, aesthetics and compatibility of the display device 10 may be increased.

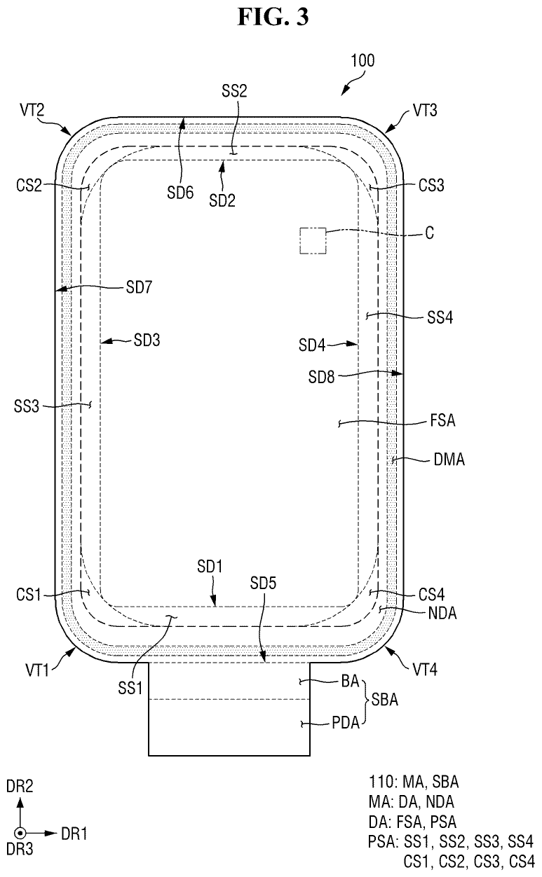

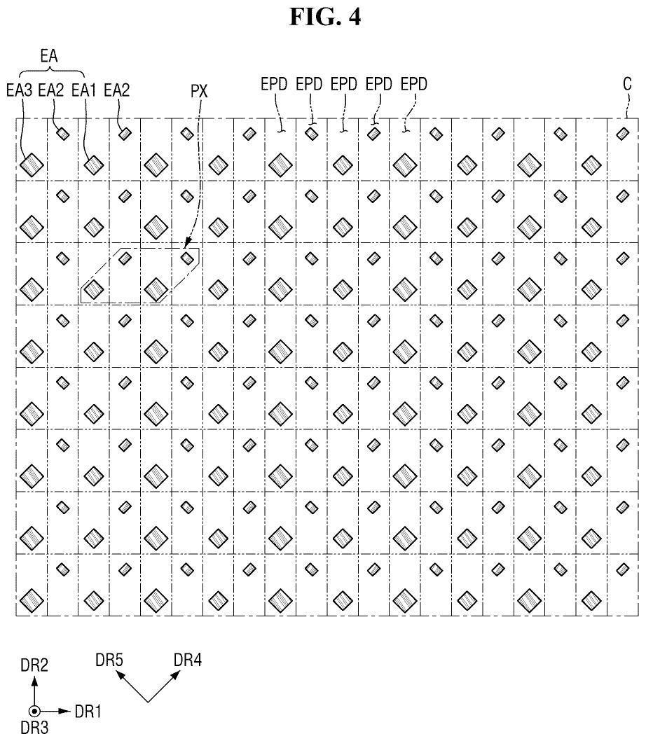

FIG. 3 is a plan view illustrating a display panel of FIG. 2. FIG. 4 is a layout diagram illustrating portion C of FIG. 3.

Referring to FIG. 3, the display panel 100 of the display device 10 according to an embodiment includes a substrate 110.

The substrate 110 may include the main area MA corresponding to the display surface, and a sub-area SBA protruding from one side of the main area MA.

The main area MA may include a display area DA where light is emitted and a non-display area NDA which is disposed around the display area DA and where light is not emitted.

Referring to FIG. 4, emission areas EA emitting light of each color and luminance to display an image may be arranged in the display area DA.

The display area DA may further include a non-emission area disposed in a spaced portion between the emission areas EA.

The emission areas EA may have a rhombic shape in a plan view or a rectangular shape in a plan view. However, this is only an example, and a shape of the emission areas EA in a plan view according to an embodiment is not limited to that illustrated in FIG. 4. That is, the emission areas EA may have a polygonal shape such as a quadrangular shape, a pentagonal shape, or a hexagonal shape in a plan view or have a circular shape or an elliptical shape, in a plan view, including a curved edge.

The emission areas EA may include first emission areas EA1 emitting light of a first color in a predetermined wavelength band, second emission areas EA2 emitting light of a second color in a wavelength band lower than that of the first color, and third emission areas EA3 emitting light of a third color in a wavelength band lower than that of the second color.

As an example, the first color may be red corresponding to a wavelength band of approximately 600 nanometer (nm) to 750 nm. The second color may be green corresponding to a wavelength band of approximately 480 nm to 560 nm. The third color may be blue corresponding to a wavelength band of approximately 370 nm to 460 nm.

The first emission areas EA1 and the third emission areas EA3 may be alternately arranged in at least one of the first direction DR1 and the second direction DR2.

The second emission areas EA2 may be arranged side by side in at least one of the first direction DR1 and the second direction DR2.

In addition, the second emission areas EA2 may neighbor or be adjacent to the first emission areas EA1 and the third emission areas EA3 in diagonal directions DR4 and DR5 crossing the first direction DR1 and the second direction DR2.

Pixels PX displaying each luminance and color may be provided by the first emission areas EA1, the second emission areas EA2, and the third emission areas EA3 adjacent to each other among such emission areas EA.

In other words, the pixels PX may be basic units displaying various colors including white at a predetermined luminance.

Each of the pixels PX may include at least one first emission area EA1, at least one second emission area EA2, and at least one third emission area EA3 adjacent to each other. Accordingly, each of the pixels PX may display various colors through mixing of light emitted from the first emission area EA1, the second emission area EA2, and the third emission area EA3 adjacent to each other.

As illustrated in FIG. 3, the display area DA of the substrate 110 of the display panel 10 according to an embodiment includes a front display area FSA disposed at the center and a peripheral display area PSA disposed around the front display area FSA.

The front display area FSA may maintain a flat shape on a plane defined by the first direction DR1 and the second direction DR2.

The front display area FSA may include a first side SD1 and a second side SD2 that extend in the first direction DR1 and oppose each other and a third side SD3 and a fourth side SD4 that extend in the second direction DR2, connect the first side SD1 and the second side SD2 to each other, and oppose each other.

The peripheral display area PSA may be disposed between the front display area FSA and the non-display area NDA. The peripheral display area PSA may have a ring shape surrounding the front display area FSA.

As illustrated in FIGS. 1 and 2, the peripheral display area PSA may be transformed into a curved shape.

As illustrated in FIG. 3, the peripheral display area PSA may include a first side area SS1, a second side area SS2, a third side area SS3, and a fourth side area SS4 in contact with the first side SD1, the second side SD2, the third side SD3, and the fourth side SD4 of the front display area FSA, respectively, a first corner area CS1 in contact with a vertex where the first side SD1 and the third side SD3 are connected to each other and disposed between the first side area SS1 and the third side area SS3, a second corner area CS2 in contact with a vertex where the second side SD2 and the third side SD3 are connected to each other and disposed between the second side area SS2 and the third side area SS3, a third corner area CS3 in contact with a vertex where the second side SD2 and the fourth side SD4 are connected to each other and disposed between the second side area SS2 and the fourth side area SS4, and a fourth corner area CS4 in contact with a vertex where the first side SD1 and the fourth side SD4 are connected to each other and disposed between the first side area SS1 and the fourth side area SS4.

The non-display area NDA may be disposed at an edge of the main area MA, and may have a ring shape surrounding the display area DA.

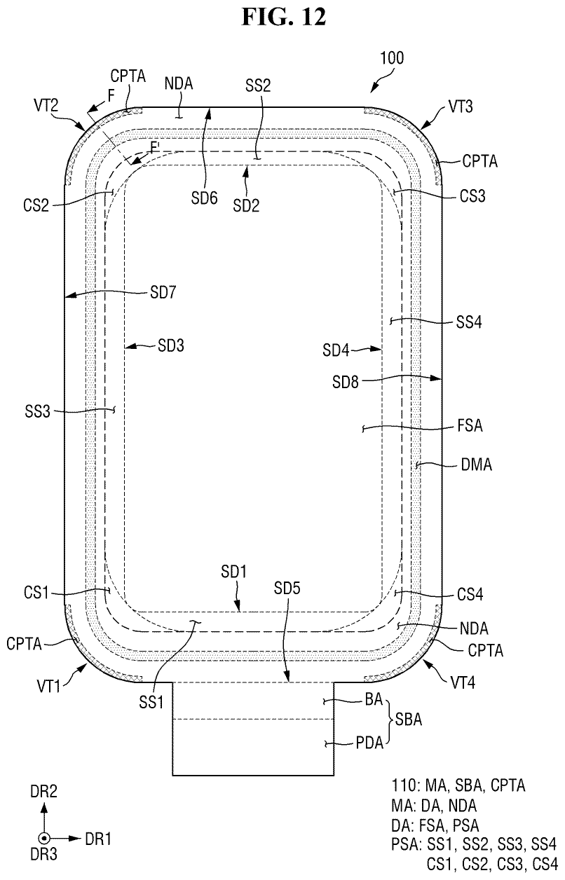

The non-display area NDA may include a dam area DMA surrounding the display area DA and spaced apart from the display area DA. At least one dam portion DM1 and DM2 (see FIG. 12) having a ring shape surrounding the display area DA may be arranged in the dam area DMA.

The sub-area SBA may face the first side SD1 of the front display area FSA. The sub-area SBA may be adjacent to the first side SD1.

The sub-area SBA may include a bending area BA transformed into a bent shape, and a pad area PDA connected to the bending area BA.

When the main area MA has a shape similar to that of the front display area FSA, the edge of the main area MA may include four sides SD5, SD6, SD7, and SD8 and four corners VT1, VT2, VT3, and VT4 where two sides extending in different directions are connected to each other.

That is, the edge of the main area MA may include fifth and sixth sides SD5 and SD6 extending in the first direction DR1 and facing each other, and seventh and eighth sides SD7 and SD8 extending in the second direction DR2, connecting between the fifth and sixth sides SD5 and SD6 and facing each other.

For example, the fifth and sixth sides SD5 and SD6 may have a shorter length compared to the seventh and eighth sides SD7 and SD8. That is, the main area MA may have a quadrangular shape in a plan view.

In another example, the corners VT1, VT2, VT3, and VT4 where each of the fifth and sixth sides SD5 and SD6 and each of the seventh and eighth sides SD7 and SD8 meet may be formed as arcs or vertices having a right-angled shape.

However, a shape of the main area MA according to embodiments is not limited to the quadrangular shape illustrated in FIG. 3, and may also be a polygonal shape other than the quadrangular shape, a circular shape, or an elliptical shape.

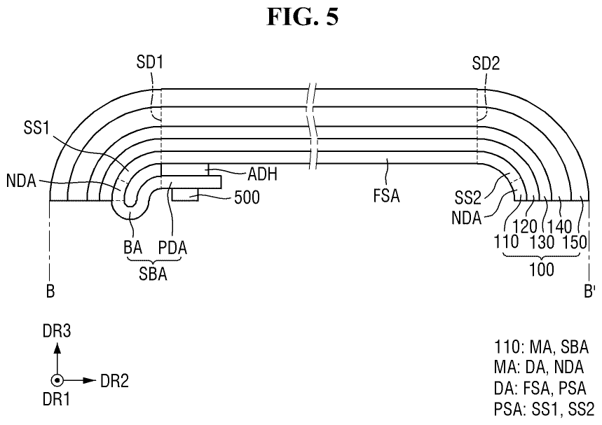

FIG. 5 is a cross-sectional view of the display panel taken along line B-B′ of FIG. 1.

Referring to FIG. 5, the display panel 100 of the display device 100 according to an embodiment includes a substrate 110, a circuit layer 120 disposed on the substrate 110, and an element layer 130 disposed on the circuit layer 120.

The substrate 110 may include a main area MA and a sub-area SBA.

The main area MA may include a display area DA and a non-display area NDA disposed around the display area DA.

The display area DA may include a front display area FSA and a peripheral display area PSA disposed around the front display area FSA and having a curved shape.

An edge of the front display area FSA may include a first side SD1 and a second side SD2 that oppose each other in the second direction DR2.

The peripheral display area PSA may include a first side area SS1 disposed between the first side SD1 of the front display area FSA and the non-display area NDA and a second side area SS2 disposed between the second side SD2 of the front display area FSA and the non-display area NDA.

In addition, as illustrated in FIG. 3, the edge of the front display area FSA may further include a third side SD3 and a fourth side SD4 that oppose each other in the first direction DR1.

The peripheral display area PSA may include a third side area SS3 disposed between the third side SD3 of the front display area FSA and the non-display area NDA and a fourth side area SS4 disposed between the fourth side SD4 of the front display area FSA and the non-display area NDA.

In addition, the peripheral display area PSA may further include a first corner area CS1 in contact with a vertex where the first side SD1 and the third side SD3 are connected to each other and disposed between the first side area SS1 and the third side area SS3, a second corner area CS2 in contact with a vertex where the second side SD2 and the third side SD3 are connected to each other and disposed between the second side area SS2 and the third side area SS3, a third corner area CS3 in contact with a vertex where the second side SD2 and the fourth side SD4 are connected to each other and disposed between the second side area SS2 and the fourth side area SS4, and a fourth corner area CS4 in contact with a vertex where the first side SD1 and the fourth side SD4 are connected to each other and disposed between the first side area SS1 and the fourth side area SS4.

According to an embodiment, the display device 10 may further include a display driving circuit 500 implemented as an integrated circuit (IC) chip and mounted in a pad area PDA of the sub-area SBA of the substrate 110.

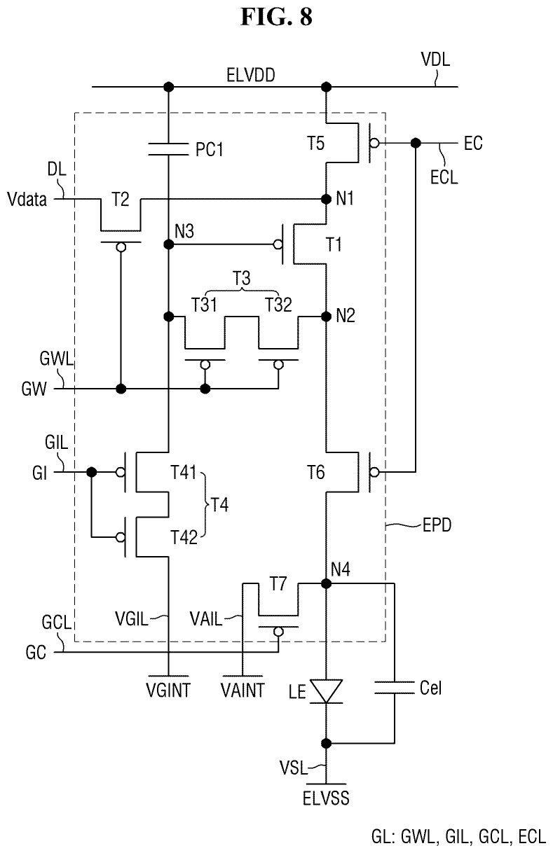

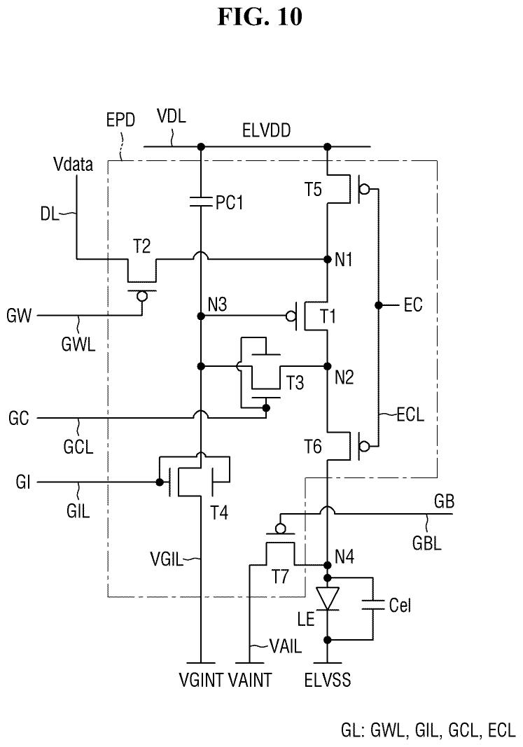

The display driving circuit 500 may supply data signals Vdata (see FIGS. 8 and 10) to data lines DL (see FIGS. 8 and 10) of the circuit layer 120.

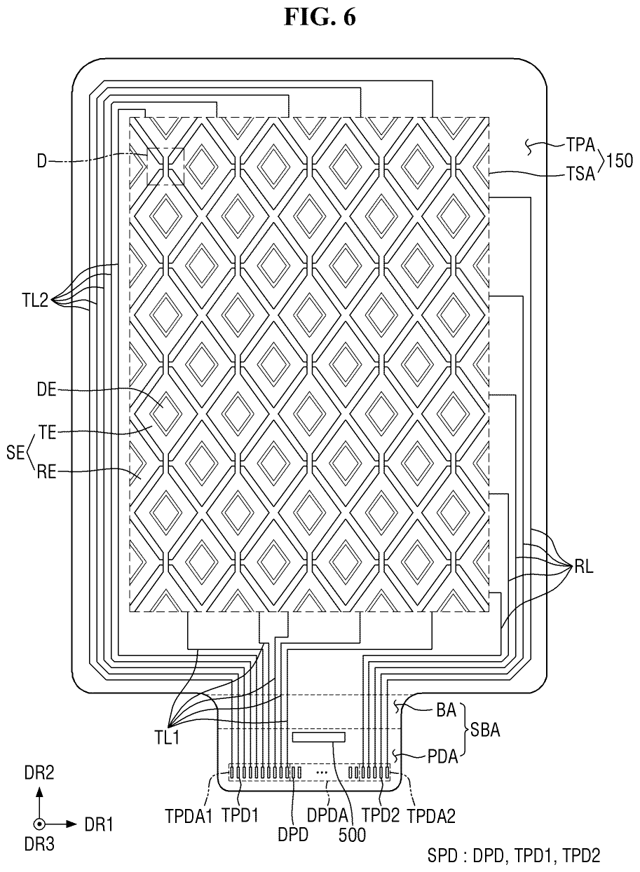

According to an embodiment, the display device 10 may further includes a circuit board bonded to the pad area PDA of the sub-area SBA of the substrate 110. The circuit board may be bonded to pads SPD (see FIG. 6) disposed in the sub-area SBA of the substrate 110 using a low-resistance and high-reliability material such as an anisotropic conductive film or a self assembly anisotropic conductive paste (SAP).

As illustrated in FIG. 4, the emission areas EA may be arranged in the display area DA.

The circuit layer 120 (see FIG. 5) may include emission pixel drivers EPD arranged side by side in the first direction DR1 and the second direction DR2.

As illustrated in FIG. 5, the element layer 130 may include light emitting elements LE (see FIGS. 8, 9, 10, and 11) respectively disposed in the emission areas EA.

The emission pixel drivers EPD (see FIGS. 4, 8, 9, 10, and 11) of the circuit layer 120 may be electrically connected to the light emitting elements LE (see FIGS. 8, 9, 10, and 11) of the element layer 130.

According to an embodiment, the display panel 100 further includes a sealing layer 140 disposed on the element layer 130 and a touch sensor layer 150 disposed on the sealing layer 140.

The sealing layer 140 may be disposed on the element layer 130, and may have a structure in which two or more inorganic films and at least one organic film are alternately stacked.

The touch sensor layer 150 may include touch electrodes for detecting a signal varying depending on a touch of a person or an object to sense a point of the main area MA where the touch of the person or the object has occurred.

According to an embodiment, the display panel 100 further includes a polarizing layer 160 disposed on the touch sensor layer 150.

The polarizing layer 160 may prevent deterioration of visibility of an image due to external light reflection by blocking external light reflected from the touch sensor layer 150, the sealing layer 140, the element layer 130, and the circuit layer 120 and interfaces between these layers.

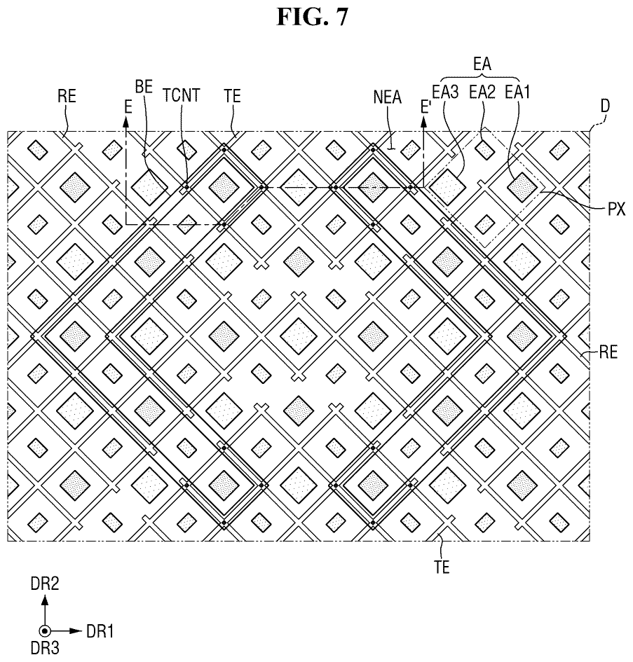

FIG. 6 is a layout diagram illustrating a touch sensor layer of FIG. 5 according to an embodiment. FIG. 7 is a detailed plan view illustrating portion D of FIG. 6.

FIGS. 6 and 7 illustrate a capacitance-type touch sensor layer 150. In this case, the display device 10 may further include a touch driving circuit for sensing a touch based on whether a change in capacitance has occurred. The touch driving circuit may be mounted on the pad area PDA of the substrate 110 or on the circuit board. However, FIGS. 6 and 7 are only an example for explanation, and the touch sensor layer 150 according to an embodiment is not limited to those illustrated in FIGS. 6 and 7.

FIG. 6 illustrates only some of components of the touch sensor layer 150 for convenience of explanation.

Referring to FIG. 6, the touch sensor layer 150 may be disposed on the main area MA of the substrate 110. The touch sensor layer 150 may include a touch sensing area TSA for sensing a user's touch and a touch peripheral area TPA disposed around the touch sensing area TSA.

The touch sensing area TSA may be wider than the display area DA and may be similar to the display area DA. Accordingly, the touch peripheral area TPA, which is a peripheral area of the touch sensing area TSA, may be similar to the non-display area NDA, which is a peripheral area of the display area DA.

As an example, the touch sensing area TSA may overlap the display area DA and an edge of the non-display area NDA in contact with the display area DA. In this case, the touch peripheral area TPA may overlap the remaining portion of the non-display area NDA that does not correspond to the touch sensing area TSA.

The touch sensor layer 150 may include sensor electrodes SE and dummy electrodes DE arranged in a matrix form in the touch sensing area TSA and generating mutual capacitance and sensor lines TL1, TL2, and RL disposed in the touch peripheral area TPA.

The sensor electrodes SE may include touch driving electrodes TE to which touch driving signals are applied and receiving electrodes RE for sensing voltages charged in mutual capacitance with the touch driving electrodes TE.

The sensor lines may include first driving lines TL1, second driving lines TL2, and sensing lines RL.

Each of the first driving lines TL1 and the second driving lines TL2 may be electrically connected to two or more touch driving electrodes TE connected to each other in the second direction DR2 among the touch driving electrodes TE.

The first driving lines TL1 may extend from one side of an edge of the touch sensing area TSA adjacent to the sub-area SBA and extend in the first direction DR1, to reach the sub-area SBA.

The second driving lines TL2 may extend from other side of the edge of the touch sensing area TSA spaced apart from the sub-area SBA and extend in the first direction DR1, and be arranged in parallel with one side of the edge of the touch sensing area TSA and extend in the second direction DR2, to reach the sub-area SBA.

The sensing lines RL may be electrically connected to two or more receiving electrodes RE connected to each other in the first direction DR1 among the receiving electrodes RE.

The receiving electrodes RE may be arranged side by side in the first direction DR1. The receiving electrodes RE neighboring each other in the first direction DR1 may be electrically connected to each other through protruding portions in the first direction DR1.

The touch driving electrodes TE may be arranged side by side in the second direction DR2. The touch driving electrodes TE neighboring each other in the second direction DR2 may be electrically connected to each other through bridge electrodes BE (see FIG. 7) in the second direction DR2.

Each of the touch driving electrodes TE and the receiving electrodes RE may have a shape that surrounds the dummy electrode DE disposed at the center thereof.

Each of the dummy electrodes DE may be spaced apart from the touch driving electrode TE and the receiving electrode RE surrounding each of the dummy electrodes DE. In an embodiment, the dummy electrode DE is maintained in a floating state.

While FIG. 6 has illustrated the touch driving electrodes TE, the receiving electrodes RE, and the dummy electrodes DE each having a rhombic shape in a plan view, embodiments of the disclosure are not limited thereto. As an example, a shape of each of the touch driving electrodes TE, the receiving electrodes RE, and the dummy electrodes DE in a plan view may be a quadrangular shape other than the rhombic shape, a polygonal shape other than the quadrangular shape, a circular shape, or an elliptical shape.

According to an embodiment, the display panel 100 includes signal pads SPD, which are disposed in the pad area PDA of the sub-area SBA of the substrate 110 and to which a circuit board is connected.

As an example, the display driving circuit 500 may be mounted in the pad area PDA.

The pad area PDA may include a display pad area DPDA adjacent to the display driving circuit 500 and a first touch pad area TPDA1 and a second touch pad area TPDA2 disposed on both sides of the display pad area DPDA, respectively.

The signal pads SPD may include display signal pads DPD disposed in the display pad area DPDA and first touch pads TPD1 and second touch pads TPD2 disposed in the first touch pad area TPDA1 and the second touch pad area TPDA2, respectively.

The display signal pads DPD may be electrically connected to the circuit layer 120 or the display driving circuit 500.

The first touch pads TPD1 may be electrically connected to the first driving lines TL1 and the second driving lines TL2.

The second touch pads TPD2 may be electrically connected to the sensing lines RL.

Referring to FIG. 7, the touch sensor layer 150 may further include bridge electrodes BE electrically connecting the touch driving electrodes TE neighboring each other in the second direction DR2 to each other.

The bridge electrodes BE may be electrically connected to the touch driving electrodes TE through touch electrode connection holes TCNT.

The touch driving electrodes TE neighboring to each other in the second direction DR2 may be electrically connected to each other through two or more bridge electrodes BE. In this way, reliability of the electrical connection between the touch driving electrodes TE may be increased.

While FIG. 7 has illustrated that two bridge electrodes BE parallel to each other are disposed between the touch driving electrodes TE neighboring each other in the second direction DR2, embodiments of the disclosure are not limited thereto.

While FIG. 7 has illustrated the bridge electrode BE having a shape including one bend, shape of the bridge electrode BE is not limited thereto.

In an embodiment, the touch driving electrode TE and the receiving electrode RE are spaced apart from each other.

The bridge electrode BE may be disposed at a different conductive layer from the touch driving electrode TE and the receiving electrode RE.

Each of the touch driving electrodes TE, the receiving electrodes RE, and the bridge electrodes BE may have a mesh shape or a shape of a net structure in a plan view. The dummy electrodes DE may also have a mesh shape or a shape of a net structure in a plan view. In this way, widths of the emission areas EA overlapping the touch driving electrodes TE, the receiving electrodes RE, the dummy electrodes DE, and the bridge electrodes BE may be reduced. Thus, reductions in light emission efficiency of the emission areas EA due to the touch driving electrodes TE, the receiving electrodes RE, the dummy electrodes DE, and the bridge electrodes BE may be alleviated.

FIG. 8 is an equivalent circuit diagram illustrating an emission pixel driver of FIG. 4 according to an embodiment.

Referring to FIG. 8, the emission pixel drivers EPD of the circuit layer 120 may be electrically connected between a first power ELVDD (e.g., a first power voltage) and the light emitting elements LE of the element layer 130. One light emitting element LE of the light emitting elements LE of the element layer 130 may be electrically connected between one emission pixel driver EPD of the emission pixel drivers EPD of the circuit layer 120 and a second power ELVSS (e.g., a second power voltage or ground voltage).

That is, an anode electrode of the light emitting element LE may be electrically connected to the emission pixel driver EPD, and second power ELVSS having a lower voltage level than first power ELVDD may be applied to a cathode electrode of the light emitting element LE.

A capacitor Ce1 connected to the light emitting element LE in parallel indicates parasitic capacitance between the anode electrode and the cathode electrode.

The circuit layer 120 may include a first power line VDL transferring the first power ELVDD, a gate initialization voltage line VGIL transferring a gate initialization voltage VGINT, and an anode initialization voltage line VAIL transferring an anode initialization voltage VAINT.

The circuit layer 120 may further include a scan write line GWL transferring a scan write signal GW, a scan initialization line GIL transferring a scan initialization signal GI, an emission control line ECL transferring an emission control signal EC, and a gate control line GCL transferring a gate control signal GC.

Meanwhile, since the scan write line GWL, the scan initialization line GIL, the emission control line ECL, and the gate control line GCL are electrically connected to the gate electrodes of the second to seventh transistors T2 to T7, hereinafter, they may be collectively referred to as gate lines GL.

One emission pixel driver EPD of the circuit layer 120 may include a first transistor T1 generating a driving current for driving the light emitting element LE, two or more transistors T2 to T7 electrically connected to the first transistor T1, and at least one capacitor PC1.

The first transistor T1 may be electrically connected between a first node N1 and a second node N2. The first node N1 is electrically connected to a first electrode (e.g., a source electrode) of the first transistor T1. The second node N2 is electrically connected to a second electrode (e.g., a drain electrode) of the first transistor T1.

The first node N1 may be electrically connected to the first power line VDL through a fifth transistor T5.

The second node N2 may be electrically connected to the anode electrode of the light emitting element LE through a sixth transistor T6.

A first capacitor PC1 may be electrically connected between the first power line VDL and a third node N3. The third node N3 is electrically connected to a gate electrode of the first transistor T1.

That is, the gate electrode of the first transistor T1 may be electrically connected to the first power line VDL through the first capacitor PC1.

Accordingly, a potential of the gate electrode of the first transistor T1 may be maintained as a voltage charged in the first capacitor PC1.

A second transistor T2 may be electrically connected between a data line DL and the first node N1.

The second transistor T2 may be electrically connected between the first electrode of the first transistor T1 and the data line DL.

That is, the first electrode of the first transistor T1 may be electrically connected to the data line DL through the second transistor T2.

The second transistor T2 may be turned on by the scan write signal GW of the scan write line GWL. For example, a gate electrode of the second transistor T2 may receive the scan write signal GW.

The fifth transistor T5 may be electrically connected between the first node N1 and the first voltage line VDL.

The sixth transistor T6 may be electrically connected between the second node N2 and a fourth node N4. The fourth node N4 is electrically connected to the anode electrode of the light emitting element LE.

That is, the fifth transistor T5 may be electrically connected between the first electrode of the first transistor T1 and the first power line VDL.

The sixth transistor T6 may be electrically connected between the second electrode of the first transistor T1 and the anode electrode of the light emitting element LE.

The fifth transistor T5 and the sixth transistor T6 may be turned on by the emission control signal EC of the emission control line ECL. For example, the gate electrodes of the fifth transistor T5 and the sixth transistor T6 may receive the emission control signal EC.

When a data signal Vdata of the data line DL is transferred to the first electrode of the first transistor T1 through the turned-on second transistor T2, a voltage difference between the gate electrode of the first transistor T1 and the first electrode of the first transistor T1 may be a difference voltage between the first power ELVDD and the data signal Vdata.

In this case, when the voltage difference between the gate electrode of the first transistor T1 and the first electrode of the first transistor T1 (i.e., a gate-source voltage difference) is greater than or equal to a threshold voltage, the first transistor T1 is turned on, such that a drain-source current of the first transistor T1 corresponding to the data signal Vdata may be generated.

Subsequently, when the fifth transistor T5 and the sixth transistor T6 are turned on, the first power source ELVDD, the first transistor T1, the light emitting element LE, and the second power source ELVSS may be connected to each other in series. Accordingly, the drain-source current of the first transistor T1 corresponding to the data signal Vdata may be supplied as the driving current of the light emitting element LE.

Accordingly, the light emitting element LE may emit light of luminance corresponding to the data signal Vdata.

A third transistor T3 may be electrically connected between the second node N2 and the third node N3. That is, the third transistor T3 may be electrically connected between the gate electrode of the first transistor T1 and the second electrode of the first transistor T1.

The third transistor T3 may include a plurality of sub-transistors connected to each other in series. As an example, the third transistor T3 may include a first sub-transistor T31 and a second sub-transistor T32.

A first electrode of the first sub-transistor T31 may be connected to the gate electrode of the first transistor T1, a second electrode of the first sub-transistor T31 may be connected to a first electrode of the second sub-transistor T32, and a second electrode of the second sub-transistor T32 may be connected to the second electrode of the first transistor T1.

In this way, it is possible to prevent the potential of the gate electrode of the first transistor T1 from changing due to a leakage current caused by the third transistor T3 that is not turned on.

The first sub-transistor T31 and the second sub-transistor T32 may be turned on by the scan write signal GW of the scan write line GWL. For example, gate terminals of the first sub-transistor T31 and the second sub-transistor T32 may receive the scan write signal GW.

When the first sub-transistor T31 and the second sub-transistor T32 are turned on, a voltage difference between the second node N2 and the third node N3 may be initialized.

A fourth transistor T4 may be electrically connected between the gate initialization voltage line VGIL and the third node N3. That is, the fourth transistor T4 may be connected between the gate electrode of the first transistor T1 and the gate initialization voltage line VGIL.

The fourth transistor T4 may include a plurality of sub-transistors connected to each other in series. As an example, the fourth transistor T4 may include a third sub-transistor T41 and a fourth sub-transistor T42.

A first electrode of the third sub-transistor T41 may be connected to the gate electrode of the first transistor T1, a second electrode of the third sub-transistor T41 may be connected to a first electrode of the fourth sub-transistor T42, and a second electrode of the fourth sub-transistor T42 may be connected to the gate initialization voltage line VGIL.

In this way, it is possible to prevent the potential of the gate electrode of the first transistor T1 from changing due to a leakage current caused by the fourth transistor T4 that is not turned on.

The third sub-transistor T41 and the fourth sub-transistor T42 may be turned on by the scan initialization signal GI of the scan initialization line GIL. For example, gate terminals of the third sub-transistor T41 and the fourth sub-transistor T42 may receive the scan initialization signal GI.

When the third sub-transistor T41 and the fourth sub-transistor T42 are turned on, a potential of the third node N3 may be initialized to the gate initialization voltage VGINT.

A seventh transistor T7 may be electrically connected between the fourth node N4 and the anode initialization voltage line VAIL. That is, the seventh transistor T7 may be electrically connected between the anode electrode of the light emitting element LE and the anode initialization voltage line VAIL.

The seventh transistor T7 may be turned on by the gate control signal GC of the gate control line GCL. For example, a gate terminal of the seventh transistor T7 may receive the gate control signal GC.

Through the turned-on seventh transistor T7, a potential of the fourth node N4 may be initialized to the anode initialization voltage VAINT.

As illustrated in FIG. 8, according to an embodiment, the first to seventh transistors T1 to T7 may be implemented as P-type metal oxide semiconductor field effect transistors (MOSFETs).

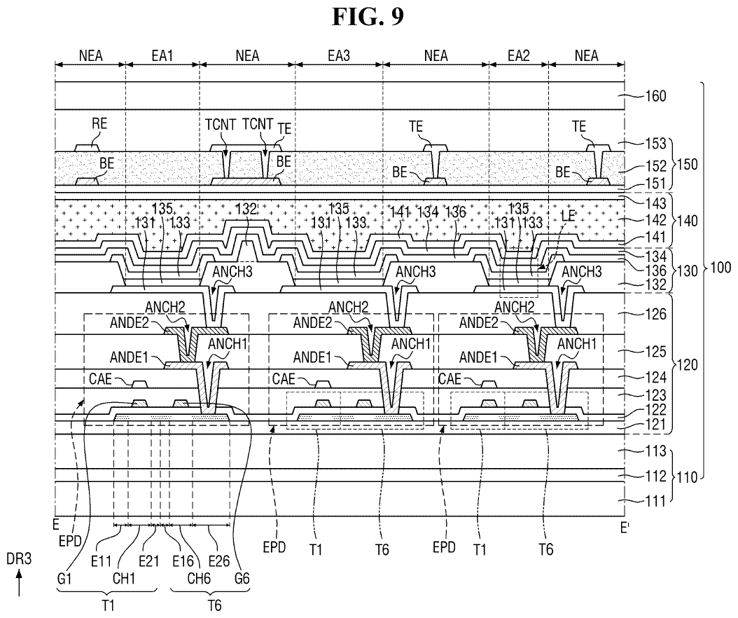

FIG. 9 is cross-sectional view taken along line E-E′ of FIG. 7 according to an embodiment of FIG. 8.

Referring to FIG. 9, the display panel 100 of the display device 100 according to an embodiment includes a substrate 110, a circuit layer 120 disposed on the substrate 110, and an element layer 130 disposed on the circuit layer 120.

The display panel 100 of the display device 10 according to an embodiment furthers include a sealing layer 140 disposed on the element layer 130, a touch sensor layer 150 disposed on the sealing layer 140, and a polarizing layer 160 disposed on the touch sensor layer 150.

According to an embodiment, the substrate 110 includes a first support layer 111, a barrier layer 112 disposed on the first support layer 111, and a second support layer 113 disposed on the barrier layer 112.

Each of the first support layer 111 and the second support layer 113 may include or be an organic insulating material that can be easily disposed with a thickness sufficient to buffer or keep out external foreign substances. As an example, each of the first support layer 111 and the second support layer 113 may include polyimide (PI). In an embodiment, the support layers 111 and 112 only include PI.

The barrier layer 112 may include an inorganic insulating material different from the first and second support layers 111 and 113 to prevent oxygen or moisture from permeating into the substrate 110. In an embodiment, the barrier layer 112 only includes an inorganic insulating material.

The circuit layer 120 may include first semiconductor layer CH1, E11, E21, CH6, E16, and E26 disposed on the substrate 110, a first gate insulating layer 122 covering the first semiconductor layer, a first gate conductive layer G1 and G6 disposed on the first gate insulating layer 122, a second gate insulating layer 123 covering the first gate conductive layer, a second gate conductive layer CAE disposed on the second gate insulating layer 123, an interlayer insulating layer 124 disposed on the second gate conductive layer CAE, a first source/drain conductive layer ANDE1 disposed on the interlayer insulating layer 124, a first planarization layer 125 covering the first source/drain conductive layer, a second source/drain conductive layer ANDE2 disposed on the first planarization layer 125, and a second planarization layer 126 covering the second source/drain conductive layer ANDE2.

According to an embodiment, the interlayer insulating layer 124 is disposed on the second gate insulating layer 123 and covers the second gate conductive layer CAE.

The circuit layer 120 may further include a buffer layer 121 covering the substrate 110.

In this case, the first semiconductor layer CH1, E11, E21, CH6, E16, and E26 may be disposed on the buffer layer 121.

The circuit layer 120 may include emission pixel drivers EPD respectively corresponding to the emission areas EA.

Each of the emission pixel drivers EPD may include a first transistor T1, second to seventh transistors T2 to T7 (see FIG. 8) electrically connected to the first transistor T1, and at least one capacitor PC1 (see FIG. 8).

FIG. 9 illustrates the first transistor T1, the sixth transistor T6, and the light emitting element LE of the emission pixel driver EPD of FIG. 8.

The first semiconductor layer disposed on the buffer layer 121 may include channel portions CH1 and CH6, first electrode portions E11 and E16, and second electrode portions E21 and E26 of each of the first to seventh transistors T1 to T7.

In each of the first transistor T1 and the sixth transistor T6, the first electrode portions E11 and E16 may be connected to one ends of the channel portions CH1 and CH6, and the second electrode portions E21 and E26 may be connected to the other ends of the channel portions CH1 and CH6.

The second electrode portion E21 of the first transistor T1 may be connected to the first electrode portion E16 of the sixth transistor T6.

The first gate conductive layer disposed on the first gate insulating layer 123 may include gate electrodes G1 and G6 of each of the first to seventh transistors T1 to T7.

In each of the first transistor T1 and the sixth transistor T6, the gate electrodes G1 and G6 may overlap the channel portions CH1 and CH6, respectively.

The second transistor T2, the first sub-transistor T31, the second sub-transistor T32, the third sub-transistor T41, the fourth sub-transistor T42, the fifth transistor T5, and the seventh transistor T7 of the emission pixel driver EPD of FIG. 8 are implemented as the same P-type MOSFETs as the first transistor T1 and the sixth transistor T6, and an overlapping description will thus be omitted below.

The second gate conductive layer disposed on the second gate insulating layer 124 may include capacitor electrodes CAE.

The capacitor electrode CAE may overlap the gate electrode G1 of the first transistor T1.

Accordingly, the first capacitor PC1 (see FIG. 8) may be provided by an overlap area between the capacitor electrode CAE and the gate electrode G1 of the first transistor T1.

The first source/drain conductive layer disposed on the interlayer insulating layer 124 may include first anode connection electrodes ANDE1.

The first anode connection electrode ANDE1 may be electrically connected to the second electrode portion E26 of the sixth transistor T6 through a first anode connection hole ANCH1.

The second source/drain conductive layer disposed on the first planarization layer 128 may include second anode connection electrodes ANDE2.

The second anode connection electrode ANDE2 may be electrically connected to the first anode connection electrode ANDE1 through a second anode connection hole ANCH2.

An anode electrode 131 of the element layer 130 may be disposed on the second planarization layer 126, and may be electrically connected to the second anode connection electrode ANDE2 through a third anode contact hole ANCH3.

Accordingly, the anode electrode 131 may be electrically connected to the second electrode portion E26 of the sixth transistor T6 through the first anode connection electrode ANDE1 and the second anode connection electrode ANDE2.

The element layer 130 disposed on the circuit layer 120 may include the light emitting elements LE respectively disposed in the emission areas EA1, EA2, and EA3.

Each of the light emitting elements LE may have a structure in which a light emitting layer 133 disposed between the anode electrode 131 and a cathode electrode 134 facing each other.

According to an embodiment, the element layer 130 includes anode electrodes 131 respectively disposed in the emission areas EA, a pixel defining layer 132 disposed in a non-emission area NEA and covering edges of the anode electrodes 131, a spacer layer 132′ disposed on a portion of the pixel defining layer 132, light emitting layers 133 respectively disposed on the anode electrodes 131, and a cathode electrode 134 disposed on the light emitting layers 133, the pixel defining layer 132, and the spacer layer 132′.

Alternatively, the light emitting elements LE may further include first common layers 135 disposed between the anode electrodes 131 and the light emitting layers 133 and a second common layer 136 disposed between the light emitting layers 133 and the cathode electrode 134, respectively.

The scaling layer 140 may be disposed on the circuit layer 120 to cover the emission layer 130.

The sealing layer 140 may block permeation of oxygen or moisture into the emission layer 130 and alleviate an electrical or physical shock to the circuit layer 120 and the emission layer 130.

The scaling layer 140 may include a first sealing layer 141 disposed on the circuit layer 120 to cover the emission layer 130; a second sealing layer 142 disposed on the first sealing layer 141 to overlap the emission layer 130; and a third sealing layer 143 disposed on the first scaling layer 141 to cover the second sealing layer 142. The sealing layers 141, 142, and 143 may include or be an inorganic insulating material.

The touch sensor layer 150 may be disposed on the sealing layer 140.

The touch sensor layer 150 may include a touch buffer layer 151 disposed on the scaling layer 140, a first touch conductive layer BE disposed on the touch buffer layer 151, a touch interlayer insulating layer 152 covering the first touch conductive layer, a second touch conductive layer RE and TE disposed on the touch interlayer insulating layer 152, and a touch planarization layer 153 covering the second touch conductive layer.

The first touch conductive layer disposed on the touch buffer layer 151 may include the bridge electrodes BE.

The second touch conductive layer disposed on the touch interlayer insulating layer 152 may include the touch driving electrodes TE and the receiving electrodes RE.

The dummy electrodes DE disposed inside each of the touch driving electrodes TE and the receiving electrodes RE, the first driving lines TL1 and the second driving lines TL2 connected to the touch driving electrodes TE, and the sensing lines RL connected to the receiving electrodes RE may be disposed at the second touch conductive layer disposed on the touch interlayer insulating layer 152, like the touch driving electrodes TE and the receiving electrodes RE.

The touch driving electrode TE may be electrically connected to the bridge electrode BE through the touch electrode connection hole TCNT that penetrates through the touch interlayer insulating layer 152.

The touch buffer layer 151 may include or be an inorganic insulating material.

According to an embodiment, each of the touch interlayer insulating layer 152 and the touch planarization layer 153 include an organic insulating material or are organic insulating layers.

The polarizing layer 160 may be disposed on the touch sensor layer 150.

Meanwhile, the emission pixel driver EPD of FIG. 8 includes the first to seventh transistors T1 to T7 implemented as the P-type MOSFETs. However, this is one example, and some of the first to seventh transistors T1 to T7 may also be implemented as N-type MOSFETs. As an example, the third transistor T3 and the fourth transistor T4 may be implemented as N-type MOSFETs.

FIG. 10 is an equivalent circuit diagram illustrating an emission pixel driver of FIG. 4 according to an embodiment.

A circuit layer 120 of a display panel 100 according to an embodiment of FIG. 10 is substantially the same as the circuit layer 120 of FIG. 8 except that the third transistor T3 and the fourth transistor T4 of the first to seventh transistors T1 to T7 of the emission pixel driver EPD are implemented as N-type MOSFETs, and an overlapping description will thus be omitted below.

According to an embodiment of FIG. 10, the third transistor T3 is electrically connected between the second node N2 and the third node N3. That is, the third transistor T3 may be electrically connected between the gate electrode of the first transistor T1 and the second electrode of the first transistor T1.

The third transistor T3 is implemented as the N-type MOSFET, and accordingly, may be turned on by the gate control signal GC of the gate control line GCL.

A voltage difference between the second node N2 and the third node N3 may be initialized through the turned-on third transistor T3.

The fourth transistor T4 may be electrically connected between the gate initialization voltage line VGIL and the third node N3. That is, the fourth transistor T4 may be connected between the gate electrode of the first transistor T1 and the gate initialization voltage line VGIL.

The fourth transistor T4 may be turned on by the scan initialization signal GI of the scan initialization line GIL.

A potential of the third node N3 may be initialized through the turned-on fourth transistor T4.

The fourth transistor T4 is implemented as the N-type MOSFET, and accordingly, the seventh transistor T7 may be turned on by a bias control signal GB of a bias control line GBL rather than the scan initialization signal GI of the scan initialization line GIL. For example, the gate electrode of the seventh transistor T7 may receive the bias control signal GB.

Meanwhile, since the bias control line GBL is electrically connected to the gate electrode of the seventh transistor T7, hereinafter the bias control line GBL will be collectively referred to as gate line GL together with the scan write line GWL, the scan initialization line GIL, the emission control line ECL, and the gate control line GCL.

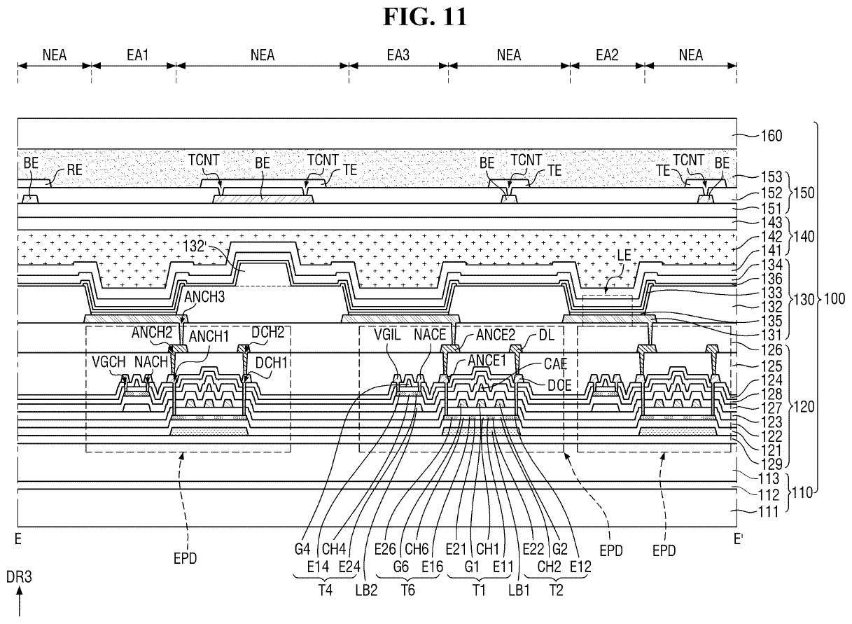

FIG. 11 is a cross-sectional view taken along line E-E′ of FIG. 7 according to an embodiment of FIG. 10.

The circuit layer 120 of the display panel 100 according to an embodiment of FIG. 11 is substantially the same as the circuit layer 120 of FIG. 9 except that it further includes a second semiconductor layer CH4, E14, and E24 and a third gate conductive layer G4 for implementing the N-type MOSFET, an auxiliary interlayer insulating layer 127, and a third gate insulating layer 128, and an overlapping description will thus be omitted below.

FIG. 11 illustrates the first transistor T1, the second transistor T2, and the sixth transistor T6 implemented as the P-type MOSFETs and the fourth transistor T4 implemented as the N-type MOSFET among the transistors T1 to T7 (see FIG. 10) of the emission pixel driver EPD and the light emitting element LE.

According to an embodiment of FIG. 11, the circuit layer 120 includes an interlayer insulating layer 124 disposed on the substrate 110, a first source/drain conductive layer ANCE1, VGIL, and DOE disposed on the interlayer insulating layer 124, a first planarization layer 125 covering the first source/drain conductive layer, a second source/drain conductive layer ANCE2 disposed on the first planarization layer 125, and a second planarization layer 126 covering the second source/drain conductive layer.

According to an embodiment of FIG. 11, the circuit layer 120 may further include a first semiconductor layer CH1, E11, E21, CH2, E12, E22, CH6, E16, and E26 disposed on the substrate 110, a first gate insulating layer 122 covering the first semiconductor layer, a first gate conductive layer G1, G2, and G6 disposed on the first gate insulating layer 122, a second gate insulating layer 123 covering the first gate conductive layer, and a second gate conductive layer CAE and LB2 disposed on the second gate insulating layer 123.

According to an embodiment of FIG. 11, the circuit layer 120 further includes the auxiliary interlayer insulating layer 127 covering the second gate conductive layer, the second semiconductor layer CH4, E14, and E24 disposed on the auxiliary interlayer insulating layer 127, the third gate insulating layer 128 covering the second semiconductor layer, and the third gate conductive layer G4 disposed on the third gate insulating layer 126 and covered by the interlayer insulating layer 124.

According to an embodiment illustrated in FIG. 11, the circuit layer 120 further includes a barrier layer 129 disposed on the substrate 110 and a first light blocking layer LB1 disposed on the barrier layer 129 and covered by the buffer layer 121.

The first semiconductor layer disposed on the buffer layer 121 may include channel portions CH1, CH2, and CH6, first electrode portions E11, E12, and E16, and second electrode portions E21, E22, and E26 of each of the first transistor T1, the second transistor T2, the fifth transistor T5 (see FIG. 10), the sixth transistor T6, and the seventh transistor T7 (see FIG. 10) implemented as the P-type MOSFETs.

The first gate conductive layer disposed on the first gate insulating layer 122 may include gate electrodes G1, G2, and G6 of each of the first transistor T1, the second transistor T2, the fifth transistor T5 (see FIG. 10), the sixth transistor T6, and the seventh transistor T7 (see FIG. 10) implemented as the P-type MOSFETs.

The fifth transistor T5 and the seventh transistor T7 have the same structure as the first transistor T1, the second transistor T2, and the sixth transistor T6, and an overlapping description will thus be omitted below.

In each of the first transistor T1, the second transistor T2, and the sixth transistor T6, the channel portions CH1, CH2, and CH6 may overlap the gate electrodes G1, G2, and G6, respectively.

The channel portion CH1 of the first transistor T1 may overlap the first light blocking layer LB1 disposed below the buffer layer 121.

In each of the first transistor T1, the second transistor T2, and the sixth transistor T6, the first electrode portions E11, E12, and E16 may be connected to one ends of the channel portions CH1, CH2, and CH6, and the second electrode portions E21, E22, and E26 may be connected to the other ends of the channel portions CH1, CH2, and CH6.

The first electrode portion E11 of the first transistor T1 may be connected to the second electrode portion E22 of the second transistor T2.

The second electrode portion E21 of the first transistor T1 may be connected to the first electrode portion E16 of the sixth transistor T6.

The second gate conductive layer disposed on the second gate insulating layer 123 may include capacitor electrodes CAE and a second light blocking layer LB2.

The second semiconductor layer disposed on the auxiliary interlayer insulating layer 127 may include a channel portion CH4, a first electrode portion E14, and a second electrode portion E24 of each of the third transistor T3 (see FIG. 10) and the fourth transistor T4 implemented as the N-type MOSFETs.

The third gate conductive layer disposed on the third gate insulating layer 128 may include a gate electrode G4 of each of the third transistor T3 (see FIG. 10) and the fourth transistor T4 implemented as the N-type MOSFETs.

In each of the third transistor T3 (see FIG. 10) and the fourth transistor T4, the channel portion CH4 may overlap the second light blocking layer LB2 disposed below the auxiliary interlayer insulating layer 127.

The channel portion CH4 of the fourth transistor T4 may overlap the gate electrode G4 of the fourth transistor T4.

The first electrode portion E14 of the fourth transistor T4 may be connected to one end of the channel portion CH4 of the fourth transistor T4, and the second electrode portion E24 of the fourth transistor T4 may be connected to the other end of the channel portion CH4 of the fourth transistor T4.

The third transistor T3 is implemented by the same N-type MOSFET as the fourth transistor T4, and an overlapping description will thus be omitted below.

The first source/drain conductive layer disposed on the interlayer insulating layer 124 may include a first anode connection electrodes ANCE1, data connection electrodes DOE, gate initialization voltage lines VGIL, and node auxiliary connection electrodes NACE.

The second source/drain conductive layer disposed on the first planarization layer 125 may include second anode connection electrodes ANCE2 and data lines DL.

The data connection electrode DOE may be electrically connected to the first electrode portion E12 of the second transistor T2 through a first data connection hole DCH1.

The data line DL may be electrically connected to the data connection electrode DOE through a second data connection hole DCH2.

Accordingly, the data line DL may be electrically connected to the first electrode portion E12 of the second transistor T2 through the data connection electrode DOE.

The gate initialization voltage line VGIL may be electrically connected to the first electrode portion E14 of the fourth transistor T4 through a gate initialization voltage connection hole VGCH.

The node auxiliary connection electrode NACE may be electrically connected to the second electrode portion E24 of the fourth transistor T4 through a node auxiliary connection hole NACH.

The emission layer 130, the sealing layer 140, the touch sensor layer 150, and the polarizing layer 160 of the display panel 100 according to an embodiment illustrated in FIG. 11 are substantially the same as those of the display panel 100 according to an embodiment illustrated in FIG. 9, and an overlapping description will thus be omitted below.

Meanwhile, according to embodiments, for ease of mass production, the display panel 100 may be manufactured in plural numbers aligned side by side on a parent substrate and then separated from the parent substrate. However, since the barrier layer 112 of the substrate 110 includes an inorganic insulating material, cracks occur in the barrier layer 112 due to physical and chemical shock during the process of separating the display panel 100 from the parent substrate.

In addition, in the display panel 100 according to embodiments, the peripheral display area PSA at the edge of the display area DA is transformed into a curved shape. Accordingly, in the process of transforming the peripheral display area PSA into a curved shape, cracks may increase in the barrier layer 112 or existing cracks in the barrier layer 112 may expand. As a result, a substrate peeling defect in which the second support layer 113 is separated from the first support layer 111 may occur, thereby reducing the lifespan and product reliability of the display device 10.

To prevent such defects, according to embodiments, the barrier layer 112 of the substrate 110 is not disposed on the entire interface between the first support layer 111 and the second support layer 113, but rather is not disposed in a crack protection area CPTA (see FIG. 12) in contact with at least a portion of the edges of the substrate 110.

That is, according to embodiments, in the crack protection area CPTA (see FIG. 12) that is in contact with at least a portion of the edges of the substrate 110 where the crack of the barrier layer 112 may increase or expand, the barrier layer 112 can be prevented from being directly exposed during the process of separating the display panel 100 from the parent substrate since the barrier layer 112 is removed.

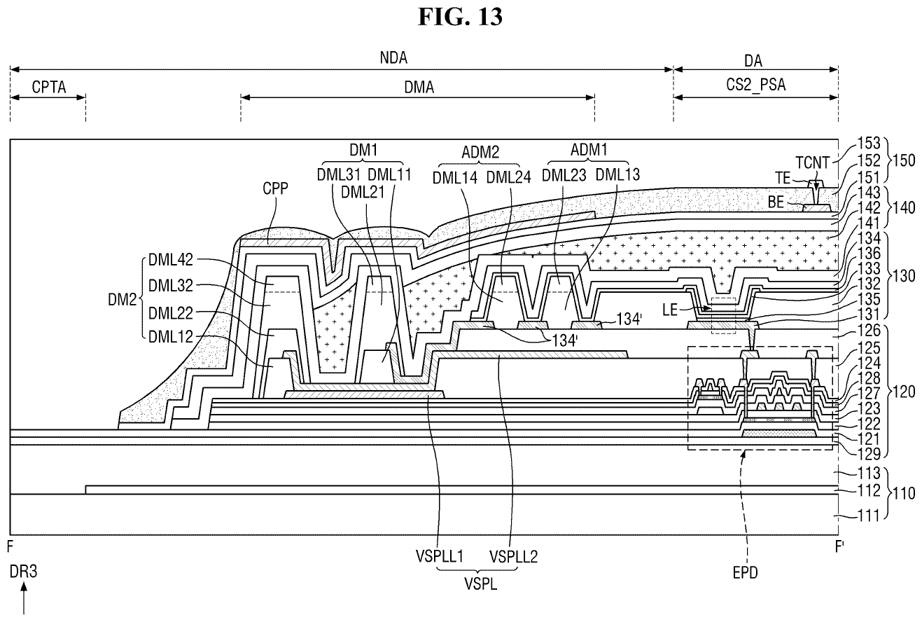

FIG. 12 is a plan view illustrating a substrate according to an embodiment. FIG. 13 is a cross-sectional view illustrating a display panel taken along line F-F′ of FIG. 12.

As illustrated in FIG. 12, the substrate 110 of the display panel 100 according to an embodiment includes a main area MA including a display area DA disposed in the center of a display surface, and a non-display area NDA disposed around the display area DA and where no light is emitted.

The main area MA may correspond to the display surface.

The edges of the main area MA may include fifth and sixth sides SD5 and SD6 extending in the first direction DR1 and facing each other, seventh and eighth sides SD7 and SD8 extending in the second direction DR2, connecting between the fifth and sixth sides SD5 and SD6 and facing each other, a first corner VT1 where the fifth side SD5 and the seventh side SD7 are connected, a second corner VT2 where the sixth side SD6 and the seventh side SD7 are connected, a third corner VT3 where the sixth side SD6 and the eighth side SD8 are connected, and a fourth corner VT4 where the fifth side SD5 and the eighth side SD8 are connected.

The substrate 110 according to an embodiment includes a crack protection area CPTA in contact with at least a portion of one or more edges of the substrate 110.

According to an embodiment, the crack protection area CPTA is in contact with the first corner VT1, the second corner VT2, the third corner VT3, and the fourth corner VT4 of the edges of the main area MA. For example, the crack protection area CPTA may include at least one of a first sub-area in contact with the first corner VT1, a second sub-area in contact with the second corner VT2, a third sub-area in contact with the third corner VT3, and a fourth sub-area in contact with the fourth corner VT4.

That is, according to an embodiment, the crack protection area CPTA is disposed between each of a first corner area CS1, a second corner area CS2, a third corner area CS3, and a fourth corner area CS4 included in the double-curvature area and the edge of the main area MA, and may extend while contacting each of the first corner VT1, the second corner VT2, the third corner VT3, and the fourth corner VT4.

In an embodiment, the crack protection area CPTA is disposed between a dam area DMA and the edge of the substrate 110. That is, the crack protection area CPTA may be in contact with at least a portion of the edges of the substrate 110 and may be spaced apart from the dam area DMA.

In addition, considering a margin in the process of separating the display panel 100 from the parent substrate, the crack protection area CPTA may be formed to have a thickness of about 75 micrometer (μm) or more in a direction perpendicular to the edge of the substrate 110.

Referring to FIG. 13, the substrate 110 of the display panel 100 of the display device 10 according to an embodiment includes a first support layer 111, a barrier layer 112 disposed on a portion of the first support layer 111, and a second support layer 113 covering the barrier layer 112.

According to an embodiment, the barrier layer 112 is disposed on the first support layer 111 in an area other than the crack protection area CPTA.

As a result, in the crack protection area CPTA, the second support layer 113 may be in direct contact with the first support layer 111 due to the removed barrier layer 112.

Accordingly, in the crack protection area CPTA, the barrier layer 112 is not disposed between the first support layer 111 and the second support layer 113. Therefore, since the barrier layer 112 may not be directly exposed during the process of separating the display panel 100 from the parent substrate, cracks in the barrier layer 112 may be reduced.

In addition, as illustrated in FIGS. 12 and 13, according to an embodiment, the barrier layer 112 overlaps the display area DA of the main area MA and extends to the non-display area NDA to further overlap the dam area DMA.

As illustrated in FIG. 13, according to an embodiment, a peripheral display area CS2_PSA of the display area DA includes emission areas EA, like the front display area FSA. Accordingly, the emission layer 130 may include light emitting elements LE disposed in the emission areas EA of the peripheral display area CS2_PSA, and the circuit layer 120 may include emission pixel drivers EPD electrically connected to the light emitting elements LE of the peripheral display area CS2_PSA. In addition, the touch sensor layer 150 may include a touch driving electrode TE and a bridge electrode BE disposed in a peripheral display area CS2_PSA and a sensing electrode RE (see FIGS. 6 and 7).

The display panel 100 of the display device 10 according to an embodiment further includes at least one dam portion DM1 and DM2 arranged in the dam area DMA of the non-display area NDA. The crack protection area CPTA may be spaced apart from the dam area DMA.

As an example, at least one dam portion disposed in the dam area DMA may include a first dam portion DM1 surrounding the display area DA and a second dam portion DM2 surrounding the first dam portion DM1.

At least one dam portion disposed in the dam area DMA may further include at least one auxiliary dam portion ADM1 and ADM2 arranged between the display area DA and the first dam portion DM1 and surrounding the display area DA.

As an example, at least one auxiliary dam portion ADM1 and ADM2 may include first dam layers DML13 and DML14 disposed on the second planarization layer 126 and second dam layers DML23 and DML24 disposed on the first dam layers DML13 and DML14, respectively.

Each of at least one dam portion DM1, DM2, ADM1, or ADM2 disposed in the dam area DMA of the non-display area NDA may include two or more dam layers DML11, DML21, and DML31; DML12, DML22, DML32, and DML42; DML13 and DML23; or DML14 and DML24.

Each of the two or more dam layers DML11, DML21, and DML31; DML12, DML22, DML32, and DML42; DML13 and DML23; or DML14 and DML24 may be disposed on the same layer as one of the first planarization layer 125, the second planarization layer 126, the pixel defining layer 132, and the spacer layer 132′ (see FIGS. 9 and 11).

The first dam portion DM1 may include a first dam layer DML11 disposed on the same layer as the second planarization layer 126, a second dam layer DML21 disposed on the same layer as the pixel defining layer 132, and a third dam layer DML31 disposed on the same layer as the spacer layer 132′.

The second dam portion DM2 may include a first dam layer DML12 disposed on the first planarization layer 125, a second dam layer DML22 disposed on the same layer as the second planarization layer 126, a third dam layer DML32 disposed on the same layer as the pixel defining layer 132, and a fourth dam layer DML42 disposed on the same layer as the spacer layer 132′.

The first dam layers DML13 and DML14 of the first auxiliary dam portion ADM1 and the second auxiliary dam portion ADM2 may be disposed on the same layer as the pixel defining layer 132.

The second dam layers DML23 and DML24 of the first auxiliary dam portion ADM1 and the second auxiliary dam portion ADM2 may be disposed on the same layer as the spacer layer 132′.

The circuit layer 120 of the display panel 100 of the display device 10 may further include a power supply line VSPL disposed in the non-display area NDA for transferring the power ELVDD or ELVSS (see FIGS. 8 and 10) for driving the light emitting elements LE (see FIGS. 8, 9, 10, and 11).

The power supply line VSPL may transfer the first power ELVDD (see FIGS. 8 and 10) or the second power ELVSS (see FIGS. 8 and 10).

As an example, the power supply line VSPL may transfer the second power ELVSS (see FIGS. 8 and 10).

The power supply line VSPL may include a first line layer VSPLL1 disposed on a first source/drain conductive layer and a second line layer VSPLL2 disposed on a second source/drain conductive layer.

The first planarization layer 125 and the second planarization layer 126 are removed in an area between the first dam portion DM1 and the second dam portion DM2 spaced apart from each other in the dam area DMA, and accordingly, the second line layer VSPLL2 may be in direct contact with the first line layer VSPLL1. Accordingly, the second line layer VSPLL2 may be electrically connected to the first line layer VSPLL1.

According to an embodiment, the circuit layer 120 further includes cathode extension lines 134′ disposed in the non-display area NDA.

The cathode extension line 134′ may be disposed on the same layer as the anode electrode 131. That is, the cathode extension line 134′ may be disposed on the second planarization layer 126. The cathode extension line 134′ may cover respective portions of the line layers VSPLL1 and VSPLL2.

When the power supply line VSPL transfers the second power ELVSS (see FIGS. 10 and 12), the cathode extension line 134′ may extend from the edge of the display area DA to the dam area DMA.

The pixel defining layer 132 and the spacer layer 132′ are removed in an area between the first dam portion DM1 and the second auxiliary dam ADM2 spaced apart from each other, and accordingly, the cathode extension line 134′ may be in direct contact with the second line layer VSPLL2 of the power supply line VSPL. Accordingly, the cathode extension line 134′ may be electrically connected to the power supply line VSPL.

The display panel 100 of the display device 10 according to an embodiment further includes a capping portion CPP overlapping the dam area DMA.

The capping portion CPP may be used to protect an inorganic insulating material positioned at the uppermost end of at least one dam portion DM1 and DM2 arranged in the dam area DMA from an etching process for disposing the second touch conductive layer TE and RE (see FIGS. 9 and 11).

According to an embodiment, at least one dam portion DM1, DM2, ADM1, or ADM2 arranged in the dam area DMA is used to limit a diffusion range of the organic insulating material of the second sealing layer 142 of the sealing layer 140, and may have a relatively great step from the substrate 110. However, the touch interlayer insulating layer 152 of the touch sensor layer 150 may include the organic insulating material, and at least one dam portion DM1, DM2, ADM1, or ADM2 may not be completely covered by the touch interlayer insulating layer 152. In this case, an inorganic insulating material positioned on at least one dam portion DM1, DM2, ADM1, or ADM2 may be exposed to the etching process for disposing the second touch conductive layer TE and RE (see FIGS. 9 and 11). To prevent this, the display panel 100 according to embodiments may include the capping portion CPP covering at least one dam portion DM1, DM2, ADM1, or ADM2.

The capping portion CPP may be disposed on the same layer as the first touch conductive layer BE (see FIGS. 9 and 11).

As described above, according to an embodiment, the crack protection area CPTA in which the barrier layer 112 of inorganic insulating material among the substrate 110 is removed contacts the four corners VT1, VT2, VT3, and VT4 of the main area MA.

That is, in the crack protection area CPTA contacting the four corners VT1, VT2, VT3, and VT4 of the main area MA, the barrier layer 112 is not exposed during the cutting process that separates the display panel 100 from the parent substrate, thereby reducing cracks of the barrier layer 112.

Accordingly, the four corners VT1, VT2, VT3, and VT4 of the main area MA may be transformed into a curved shape with double-curvature, together with the first corner area CS1, the second corner area CS2, the third corner area CS3, and the fourth corner area CS4. Therefore, even when a relatively high bending stress is applied, a separation defect of the substrate 110 due to cracks in the barrier layer 112 can be prevented.

According to an embodiment, the crack protection area CPTA contacts not only the four corners VT1, VT2, VT3, and VT4 of the main area MA among the edges of the substrate 110, but also other portions of the edges of the substrate 110.

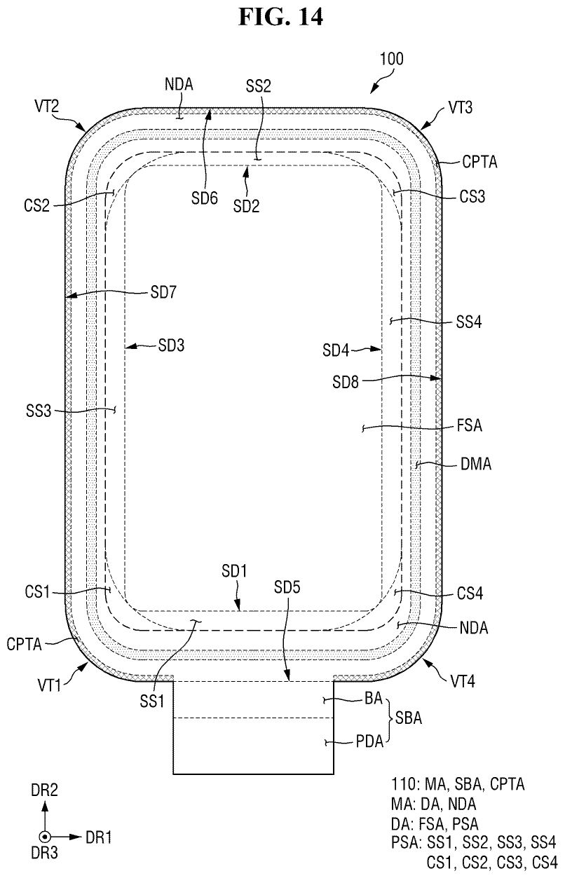

FIGS. 14, 15, 16, 17, 18, and 19 are plan views of substrates according to embodiments.

A display panel 100 of the display device 10 according to an embodiment of FIG. 14 is substantially the same as the display device according to an embodiment illustrated in FIGS. 12 and 13 except that the crack protection area CPTA of the substrate 110 is in contact with the remaining portions of the edge of the main area MA other than the portion connected to the sub-area SBA, and an overlapping description will thus be omitted below. For example, the crack protection area CPTA may entirely surround the non-display area NDA except for a portion adjacent the sub-area SBA.

As illustrated in FIG. 14, according to embodiments, the sub-area SBA may protrude from at least a portion of the fifth side SD5 of the main area MA.

According to an embodiment of FIG. 14, the crack protection area CPTA is further in contact with the seventh side SD7, the sixth side SD6, and the eighth side SD8 among the edges of the main area MA, and is further in contact with a portion of the fifth side SD5 of the main area MA other than the portion contacting the sub-area SBA.

The crack protection area CPTA may be disposed between a dam area DMA and the edge of the substrate 110. That is, the crack protection area CPTA may be in contact with at least a portion of the edges of the substrate 110 and may be spaced apart from the dam area DMA.

In addition, considering a margin of the process of separating the display panel 100 from the parent substrate, the crack protection area CPTA may be formed to have a thickness of about 75 μm or more in a direction perpendicular to the edge of the substrate 110.

According to an embodiment, the edge of the main area MA other than the portion in contact with the sub-area SBA is exposed to a cutting process that separates the display panel 100 from the parent substrate.

According to the embodiment of FIG. 14, the crack protection area CPTA from which the barrier layer 112 is removed is in contact with the edges of the main area MA other than the portion which is in contact with the sub-area SBA, and thus, the barrier layer 112 should not be exposed to the cutting process at the edge of the main area MA. Accordingly, cracks in the barrier layer 112 can be further reduced.

Accordingly, as the peripheral display area PSA of the display area DA is transformed into a curved shape, even when a bending stress is applied to the edge of the main area MA, a separation defect of the substrate 110 due to cracks in the barrier layer 112 can be prevented.

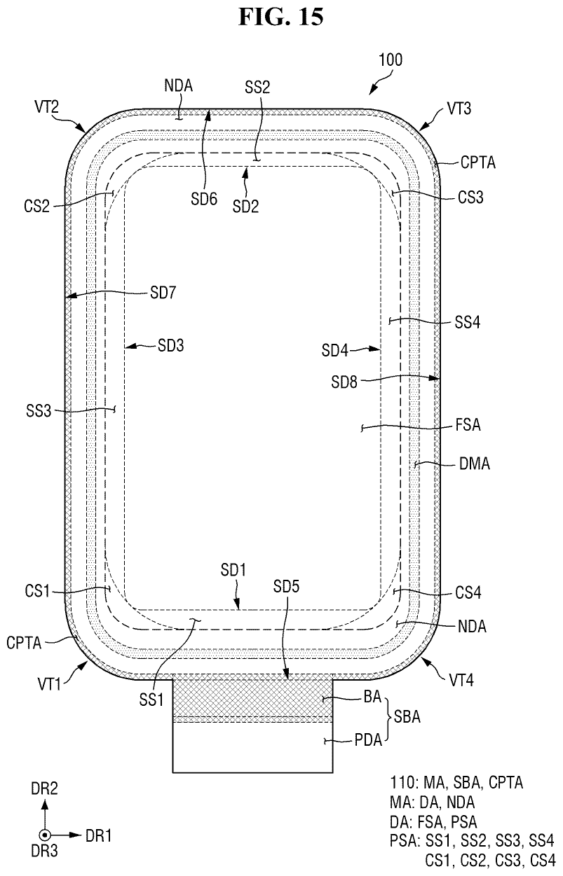

A display panel 100 of the display device 10 according to an embodiment of FIG. 15 is substantially the same as the display device according to an embodiment illustrated in FIG. 14 except that the crack protection area CPTA of the substrate 110 further includes a bending area BA of the sub-area SBA, and an overlapping description will thus be omitted below.

According to an embodiment, a pad area PDA of the sub-area SBA is disposed on the rear surface of the substrate 110 by the bending area BA transformed into a bent shape and may overlap the main area MA.

According to an embodiment of FIG. 15, the crack protection area CPTA may not only be in contact with the edge of the main area MA but also include the bending area BA.

In this way, the barrier layer 112 of the substrate 110 may be removed from the bending area BA, thereby reducing cracks of the barrier layer 112 due to bending stress caused by the bent bending area BA.

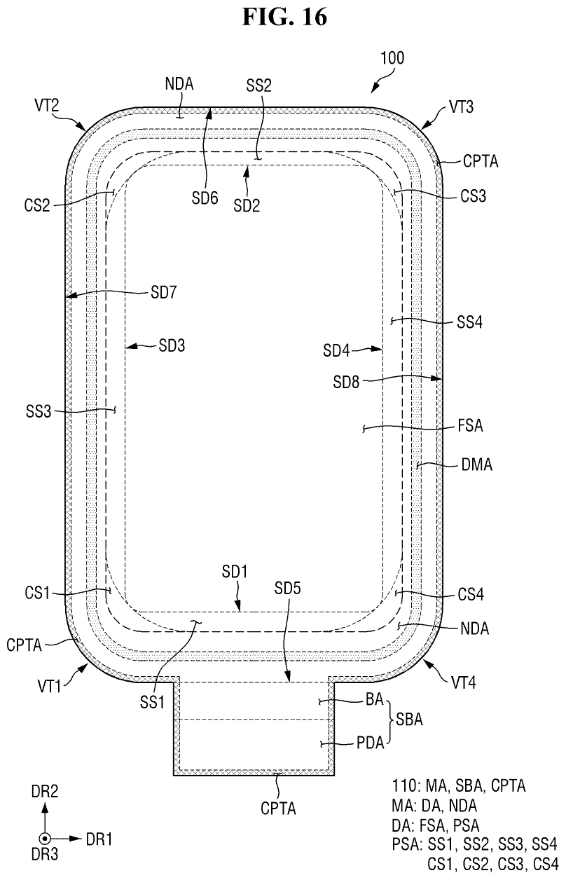

A display panel 100 of the display device 10 according to an embodiment of FIG. 16 is substantially the same as the display device illustrated in FIG. 14 except that the crack protection area CPTA of the substrate 110 is in further contact with an edge of the sub-area SBA other than the portion of the sub-area SBA connected to the main area MA, and an overlapping description will thus be omitted below.

According to an embodiment, an edge of the sub-area SBA other than the portion in contact with the main area MA is exposed to the cutting process that separates the display panel 100 from the parent substrate.

According to an embodiment of FIG. 16, the crack protection area CPTA from which the barrier layer 112 is removed is in contact with a portion exposed to the cutting process at each of the edge of the main area MA and the edge of the sub-area SBA. That is, since the barrier layer 112 is removed from the edge of the substrate 110 on which the cutting process is performed, the barrier layer 112 is not exposed to the cutting process, thereby further reducing cracks of the barrier layer 112.

Accordingly, a separation defect of the substrate 110 due to cracks in the barrier layer 112 can be further prevented.

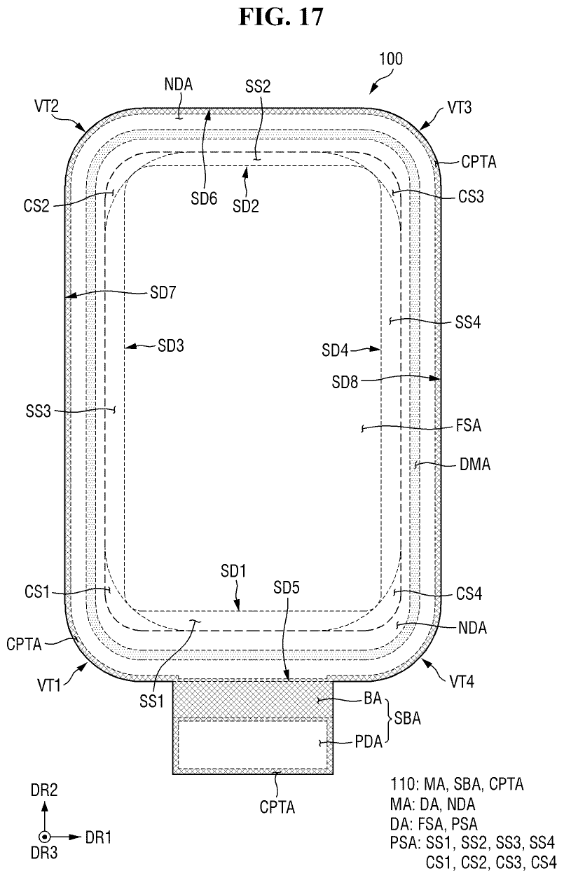

A display panel 100 of the display device 10 according to an embodiment of FIG. 17 is a combination of the embodiment of FIG. 15 and the embodiment of FIG. 16, and an overlapping description will thus be omitted below.

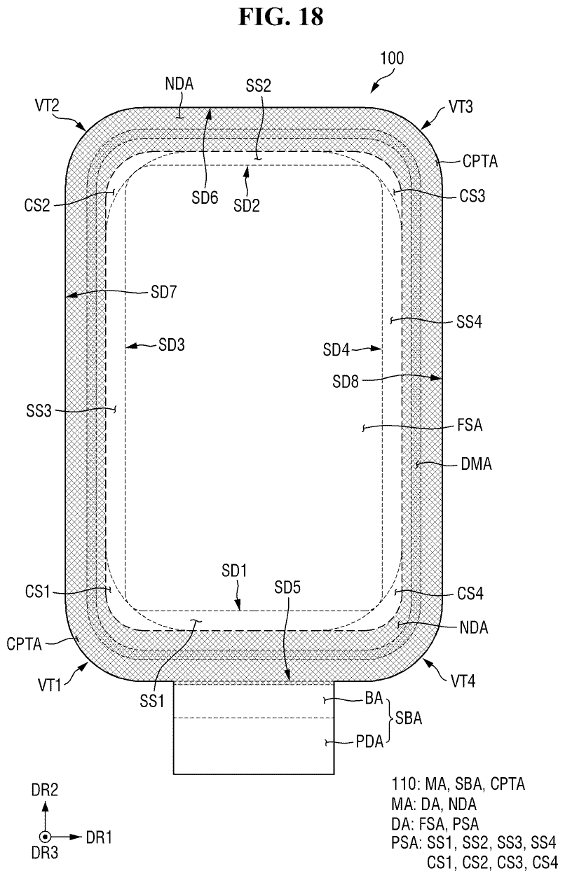

A display panel 100 of the display device 10 according to an embodiment of FIG. 18 is substantially the same as the embodiments illustrated in FIGS. 1 to 17 except that the crack protection area CPTA includes a non-display area NDA of the main area MA, and an overlapping description will thus be omitted below.

According to an embodiment of FIG. 18, the crack protection area CPTA may include the non-display area NDA which is the main area MA other than the display area DA.

That is, according to an embodiment of FIG. 18, the barrier layer 112 overlaps only the display area of the main area MA.

In this way, the first semiconductor layer CH1, E11, E21, CH6, E16, and E26 (see FIG. 9) and CH1, E11, E21, CH2, E12, E22, CH6, E16, and E26 (see FIG. 11) of the display area DA may be disposed relatively flat on the substrate 110 including the barrier layer 112. Therefore, the characteristic uniformity of P-type MOSFET transistors T1 to T7 (see FIG. 8) and T1, T2, and T5 to T7 (see FIG. 10) included in each emission pixel driver EPD may be prevented from deteriorating.

That is, while the characteristic uniformity of the P-type MOSFET transistors T1 to T7 (see FIG. 8) and T1, T2, and T5 to T7 (see FIG. 10) disposed in the display area DA may be prevented from deteriorating, the barrier layer 112 may be spaced apart from the edge of the main area MA as much as possible, and thus, cracks in the barrier layer 112 can be further reduced.

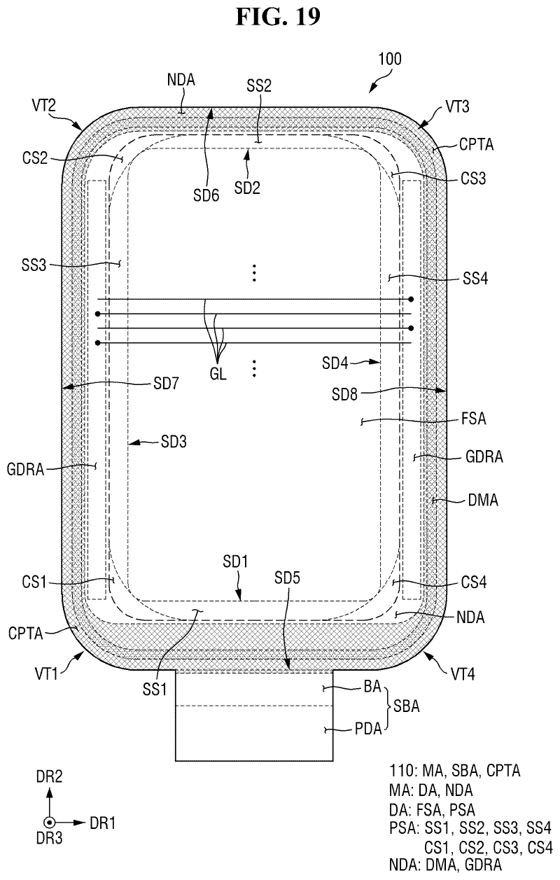

A display panel 100 of the display device 10 according to an embodiment of FIG. 19 is substantially the same as the embodiments illustrated in FIG. 18 except that the circuit layer 120 further includes a gate driver disposed in a gate circuit area GDRA among the non-display area NDA and that the barrier layer 112 extends in the non-display area NDA to further overlap the gate circuit area GDRA, and an overlapping description will thus be omitted below.

According to an embodiment, the display panel 100 may further include a gate driver (e.g., a gate driver circuit) supplying gate signals to gate lines GL.

The gate lines GL may extend in the display area DA in the first direction DR1.

The gate lines GL may include scan write lines GWL (see FIGS. 8 and 10), scan initialization lines GIL (see FIGS. 8 and 10), emission control lines ECL (see FIGS. 8 and 10), and gate control lines GCL (see FIGS. 8 and 10).

The gate lines GL may further include bias control lines GBL (see FIG. 10).

According to an embodiment of FIG. 19, the gate driver may be installed in the circuit layer 120.

That is, according to an embodiment of FIG. 19, the non-display area NDA may further include the gate circuit area GDRA facing at least one side of the display area DA in the first direction DR1.

The circuit layer 120 may include the gate driver disposed in the gate circuit area GDRA of the non-display area NDA.

The gate driver may include at least one P-type MOSFET transistor.

According to an embodiment of FIG. 19, the barrier layer 112 may extend to the non-display area NDA to further overlap the gate circuit area GDRA. In this way, the gate driver of the gate circuit area GDRA may be disposed to be relatively flat on the substrate 110 including the barrier layer 112. Accordingly, while the characteristic uniformity of the transistor included in the gate driver may be prevented from deteriorating, the barrier layer 112 may be spaced apart from the edge of the main area MA as much as possible, and thus, cracks in the barrier layer 112 can be further reduced.

However, the effects of the present disclosure are not restricted to those discussed above. The above and other effects of the present disclosure may become more apparent to one of ordinary skill in the art to which the present disclosure pertains by referencing the claims.

What is claimed is:

1. A display device comprising:
a display panel to emit light for displaying an image,
wherein the display panel comprises:
a substrate; and
a circuit layer disposed on the substrate; and
an emission layer disposed on the circuit layer,
a main area of the substrate includes a display area where emission areas are arranged and a non-display area disposed around the display area,
the display area includes a front display area and a peripheral display area disposed around the front display area and having a curved shape,
the substrate comprises:
a first support layer;
a barrier layer disposed on a portion of the first support layer; and
a second support layer covering the barrier layer,
the substrate further includes a crack protection area in contact with at least a portion of an edge of the substrate, and
the second support layer is in contact with the first support layer in the crack protection area.

2. The display device of claim 1,
wherein the front display area comprises a first side and a second side that extend in a first direction and oppose each other and a third side and a fourth side that extend in a second direction crossing the first direction and oppose each other,
the peripheral display area comprises:
a first side area, a second side area, a third side area, and a fourth side area in contact with the first side, the second side, the third side, and the fourth side of the front display area, respectively;
a first corner area in contact with a vertex where the first side and the third side meet and disposed between the first side area and the third side area;
a second corner area in contact with a vertex where the second side and the third side meet and disposed between the second side area and the third side area;
a third corner area in contact with a vertex where the second side and the fourth side meet and disposed between the second side area and the fourth side area; and
a fourth corner area in contact with a vertex where the first side and the fourth side meet and disposed between the first side area and the fourth side area.

3. The display device of claim 2, wherein the barrier layer overlaps the display area of the main area.

4. The display device of claim 3,
wherein the emission layer includes light emitting elements respectively disposed in the emission areas, and
the circuit layer comprises:
emission pixel drivers arranged in the first direction and the second direction in the display area and electrically connected to the light emitting elements, respectively;
gate lines extending in the first direction and transmitting gate signals to the emission pixel drivers; and
a gate driver disposed in a gate circuit area facing at least one side of the display area among the non-display area in the first direction and supplying gate signals to the gate lines,
wherein the barrier layer extends to the non-display area to further overlap the gate circuit area.

5. The display device of claim 3, wherein the display panel further comprises:
a sealing layer disposed on the emission layer; and
at least one dam portion arranged in a dam area of the non-display area surrounding the display area and spaced apart from the display area,
wherein the barrier layer extends to the non-display area and further overlaps the dam area, and
the crack protection area is disposed between the dam area and the edge of the substrate.

6. The display device of claim 5, wherein the edge of the main area comprises:
fifth and sixth sides extending in a first direction and facing each other;
seventh and eighth sides extending in a second direction crossing the first direction and facing each other;
a first corner where the fifth side and the seventh side meet;
a second corner where the sixth side and the seventh side meet;
a third corner where the sixth side and the eighth side meet; and
a fourth corner where the fifth side and the eighth side meet, and
the crack protection area is in contact with at least one of the first corner, the second corner, the third corner, and the fourth corner.

7. The display device of claim 6,
wherein the substrate further includes a sub-area protruding from at least a portion of the fifth side,
the crack protection area is in further contact with the seventh side, the sixth side, and the eighth side, and
the crack protection area is in further contact with a portion of the fifth side of the edge of the main area other than a portion in contact with the sub-area.

8. The display device of claim 7,
wherein the sub-area includes a bending area adjacent to the main area, and a pad area adjacent to the bending area, and
the crack protection area includes the bending area.

9. The display device of claim 7, wherein the crack protection area is in further contact with a portion of the edge of the sub-area other than a portion of the sub-area adjacent to the main area.

10. The display device of claim 2, wherein each of the first support layer and the second support layer includes an organic insulating material, and the barrier layer includes an inorganic insulating material.

11. The display device of claim 2, wherein the circuit layer further comprises:
a first semiconductor layer disposed on the substrate;
a first gate insulating layer covering the first semiconductor layer;
a first gate conductive layer disposed on the first gate insulating layer;
a second gate insulating layer covering the first gate conductive layer;
a second gate conductive layer disposed on the second gate insulating layer;
an interlayer insulating layer disposed on the second gate insulating layer and the second gate conductive layer;
a first source/drain conductive layer disposed on the interlayer insulating layer;
a first planarization layer covering the first source/drain conductive layer;
a second source/drain conductive layer disposed on the first planarization layer; and
a second planarization layer covering the second source/drain conductive layer.

12. The display device of claim 11, wherein the circuit layer further comprises:
an auxiliary interlayer insulating layer covering the second gate conductive layer;
a second semiconductor layer disposed on the auxiliary interlayer insulating layer;
a third gate insulating layer covering the second semiconductor layer; and
a third gate conductive layer disposed on the third gate insulating layer and covered by the interlayer insulating layer.

13. The display device of claim 2, further comprising:
a bracket supporting the display panel; and
a cover window disposed on the display panel and coupled to the bracket,
wherein the peripheral display area has a shape curved toward the bracket.

14. A display device comprising:
a display panel to emit light for displaying an image;
a bracket supporting the display panel; and
a cover window disposed on the display panel and coupled to the bracket,
wherein the display panel comprises:
a substrate;
a circuit layer disposed on the substrate; and
an emission layer disposed on the circuit layer,
a main area of the substrate includes a display area where emission areas are arranged and a non-display area disposed around the display area,
the display area includes a front display area and a peripheral display area disposed around the front display area and having a shape curved toward the bracket,
the substrate comprises:
a first support layer;
a barrier layer disposed on a portion of the first support layer and including a material different from the first support layer; and
a second support layer covering the barrier layer and including a same material as the first support layer,
the substrate further includes a crack protection area in contact with at least a portion of an edge of the substrate, and
the second support layer is in contact with the first support layer in the crack protection area.

15. The display device of claim 14,
wherein the front display area comprises a first side and a second side extending in a first direction and facing each other and a third side and a fourth side extending in a second direction crossing the first direction and facing each other,
the peripheral display area comprises:
a first side area, a second side area, a third side area, and a fourth side area in contact with the first side, the second side, the third side, and the fourth side of the front display area, respectively;
a first corner area in contact with a vertex where the first side and the third side meet and disposed between the first side area and the third side area;
a second corner area in contact with a vertex where the second side and the third side meet and disposed between the second side area and the third side area;
a third corner area in contact with a vertex where the second side and the fourth side meet and disposed between the second side area and the fourth side area; and
a fourth corner area in contact with a vertex where the first side and the fourth side meet and disposed between the first side area and the fourth side area.

16. The display device of claim 15, wherein the barrier layer overlaps the display area of the main area.

17. The display device of claim 16, wherein the emission layer includes light emitting elements respectively disposed in the emission areas, and the circuit layer comprises:
emission pixel drivers arranged in the first direction and the second direction in the display area and electrically connected to the light emitting elements, respectively;
gate lines extending in the first direction and transmitting gate signals to the emission pixel drivers; and
a gate driver disposed in a gate circuit area facing at least one side of the display area among the non-display area in the first direction and supplying gate signals to the gate lines,
wherein the barrier layer extends to the non-display area to further overlap the gate circuit area.

18. The display device of claim 16,
wherein the display panel further comprises:
a sealing layer disposed on the emission layer; and
at least one dam portion arranged in a dam area of the non-display area surrounding the display area and spaced apart from the display area,
an edge of the main area comprises:
fifth and sixth sides extending in a first direction and facing each other;
seventh and eighth sides extending in a second direction crossing the first direction and facing each other;
a first corner where the fifth side and the seventh side meet;
a second corner where the sixth side and the seventh side meet;
a third corner where the sixth side and the eighth side meet; and
a fourth corner where the fifth side and the eighth side meet,
the crack protection area is in contact with the first corner, the second corner, the third corner, and the fourth corner and disposed between the dam area and the edge of the substrate, and
the barrier layer extends to the non-display area to further overlap the dam area.

19. The display device of claim 18,
wherein the substrate further includes a sub-area protruding from a portion of the fifth side,
the crack protection area is in further contact with the seventh side, the sixth side, and the eighth side, and
the crack protection area is in further contact with a portion of the fifth side of the edge of the main area other than a portion of the main area in contact with the sub-area.

20. The display device of claim 19, wherein the crack protection area is in further contact with a portion of the edge of the sub-area other than a portion of the sub-area adjacent to the main area.
